(19) United States
(12) Patent Application Publication
(10) Pub. No.: US 2026/0370384 A1
(43) Pub. Date: Nov. 19, 2026

(54) CONDITIONS FOR LOW-DENSITY PARITY CHECK CODES

(71) Applicant: QUALCOMM Incorporated, San Diego, CA (US)

(72) Inventors: Pinar SEN, San Diego, CA (US); Wei YANG, San Diego, CA (US); Jing JIANG, San Diego, CA (US)

(21) Appl. No.: 19/660,505

(22) Filed: Apr. 28, 2026

Related U.S. Application Data
(60) Provisional application No. 63/798,885, filed on May 2, 2025.

(51) Int. Cl. H04L 1/00

(52) U.S. Cl. CPC H04L 1/0076; H04L 1/0057

(57) ABSTRACT

Various aspects of the present disclosure generally relate to wireless communication. In some aspects, a first wireless communication device may obtain an encoded communication. The first wireless communication device may decode, using a low-density parity check (LDPC) code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge. Numerous other aspects are described.

### CROSS-REFERENCE TO RELATED APPLICATION

This Patent Application claims priority to U.S. Provisional Patent Application No. 63/798,885, filed on May 2, 2025, entitled “CONDITIONS FOR LOW-DENSITY PARITY CHECK CODES,” and assigned to the assignee hereof. The disclosure of the prior Application is considered part of and is incorporated by reference into this Patent Application.

### INTRODUCTION

Aspects of the present disclosure generally relate to wireless communication and specifically relate to techniques, apparatuses, and methods associated with one or more conditions for channel coding.

Wireless communication systems are widely deployed to provide various services, which may involve carrying or supporting voice, text, other messaging, video, data, or other traffic. Typical wireless communication systems may employ multiple-access radio access technologies (RATs) capable of supporting communication among multiple wireless communication devices including user devices or other devices by sharing the available system resources (for example, time domain resources, frequency domain resources, spatial domain resources, or device transmit power, among other examples). Such multiple-access RATs are supported by technological advancements that have been adopted in various telecommunication standards, which define common protocols that enable different wireless communication devices to communicate on a local, municipal, national, regional, or global level. An example telecommunication standard is New Radio (NR). NR, which also may be referred to as 5G, is part of a continuous mobile broadband evolution promulgated by the Third Generation Partnership Project (3GPP). As the demand for connectivity continues to increase, further improvements in NR may be implemented, and other RATs, such as 6G and beyond, may be introduced to enable new applications and facilitate new use cases.

### SUMMARY

Some aspects described herein relate to an apparatus at a first wireless communication device. The apparatus may include one or more memories and one or more processors coupled with the one or more memories. The one or more processors may be configured to cause the first wireless communication device to obtain an encoded communication. The one or more processors may be configured to cause the first wireless communication device to decode, using a low-density parity check (LDPC) code, the encoded communication to obtain a communication, where the LDPC code is associated with a base graph that includes a single punctured node and one or more check nodes, and where the base graph is in accordance with a check degree condition that indicates that at least one check node, of the one or more check nodes, is connected to the single punctured node via a single edge.

Some aspects described herein relate to an apparatus at a first wireless communication device. The apparatus may include one or more memories and one or more processors coupled with the one or more memories. The one or more processors may be configured to cause the first wireless communication device to encode, using an LDPC code, a communication to obtain an encoded communication, where the LDPC code is associated with a base graph that includes a single punctured node and one or more check nodes, and where the base graph is in accordance with a check degree condition that indicates that at least one check node, of the one or more check nodes, is connected to the single punctured node via a single edge. The one or more processors may be configured to cause the first wireless communication device to provide, to a second wireless communication device, the encoded communication.

Some aspects described herein relate to an apparatus at a first wireless communication device. The apparatus may include one or more memories and one or more processors coupled with the one or more memories. The one or more processors may be configured to cause the first wireless communication device to obtain an encoded communication. The one or more processors may be configured to cause the first wireless communication device to decode, using an LDPC code, the encoded communication to obtain a communication, where the LDPC code is associated with a base graph that is in accordance with a stability metric condition.

Some aspects described herein relate to an apparatus at a first wireless communication device. The apparatus may include one or more memories and one or more processors coupled with the one or more memories. The one or more processors may be configured to cause the first wireless communication device to encode, using an LDPC code, a communication to obtain an encoded communication, where the LDPC code is associated with a base graph that is in accordance with a stability metric condition. The one or more processors may be configured to cause the first wireless communication device to provide the encoded communication.

Some aspects described herein relate to a method of wireless communication performed at a first wireless communication device. The method may include obtaining an encoded communication. The method may include decoding, using an LDPC code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge.

Some aspects described herein relate to a method of wireless communication performed at a first wireless communication device. The method may include encoding, using an LDPC code, a communication to obtain an encoded communication, the LDPC code being associated with a base graph that includes a single punctured node and one or more check nodes, and the base graph being in accordance with a check degree condition that indicates that at least one check node, of the one or more check nodes, is connected to the single punctured node via a single edge. The method may include providing, to a second wireless communication device, the encoded communication.

Some aspects described herein relate to a method of wireless communication performed at a first wireless communication device. The method may include obtaining an encoded communication. The method may include decoding, using an LDPC code, the encoded communication to obtain a communication, the LDPC code being associated with a base graph that is in accordance with a stability metric condition.

Some aspects described herein relate to a method of wireless communication performed at a first wireless communication device. The method may include encoding, using an LDPC code, a communication to obtain an encoded communication, the LDPC code being associated with a base graph that is in accordance with a stability metric condition. The method may include providing the encoded communication.

Some aspects described herein relate to a non-transitory computer-readable medium that stores a set of instructions for wireless communication by a wireless communication device. The set of instructions, when executed by one or more processors of the wireless communication device, may cause the wireless communication device to obtain an encoded communication. The set of instructions, when executed by one or more processors of the wireless communication device, may cause the wireless communication device to decode, using an LDPC code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge.

Some aspects described herein relate to a non-transitory computer-readable medium that stores a set of instructions for wireless communication by a wireless communication device. The set of instructions, when executed by one or more processors of the wireless communication device, may cause the wireless communication device to encode, using an LDPC code, a communication to obtain an encoded communication, the LDPC code being associated with a base graph that includes a single punctured node and one or more check nodes, and the base graph being in accordance with a check degree condition that indicates that at least one check node, of the one or more check nodes, is connected to the single punctured node via a single edge. The set of instructions, when executed by one or more processors of the wireless communication device, may cause the wireless communication device to provide, to a second wireless communication device, the encoded communication.

Some aspects described herein relate to a non-transitory computer-readable medium that stores a set of instructions for wireless communication by a wireless communication device. The set of instructions, when executed by one or more processors of the wireless communication device, may cause the wireless communication device to obtain an encoded communication. The set of instructions, when executed by one or more processors of the wireless communication device, may cause the wireless communication device to decode, using an LDPC code, the encoded communication to obtain a communication, the LDPC code being associated with a base graph that is in accordance with a stability metric condition.

Some aspects described herein relate to a non-transitory computer-readable medium that stores a set of instructions for wireless communication by a wireless communication device. The set of instructions, when executed by one or more processors of the wireless communication device, may cause the wireless communication device to encode, using an LDPC code, a communication to obtain an encoded communication, the LDPC code being associated with a base graph that is in accordance with a stability metric condition. The set of instructions, when executed by one or more processors of the wireless communication device, may cause the wireless communication device to provide the encoded communication.

Some aspects described herein relate to an apparatus for wireless communication. The apparatus may include means for obtaining an encoded communication. The apparatus may include means for decoding, using an LDPC code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge.

Some aspects described herein relate to an apparatus for wireless communication. The apparatus may include means for encoding, using an LDPC code, a communication to obtain an encoded communication, the LDPC code being associated with a base graph that includes a single punctured node and one or more check nodes, and the base graph being in accordance with a check degree condition that indicates that at least one check node, of the one or more check nodes, is connected to the single punctured node via a single edge. The apparatus may include means for providing, to a second wireless communication device, the encoded communication.

Some aspects described herein relate to an apparatus for wireless communication. The apparatus may include means for obtaining an encoded communication. The apparatus may include means for decoding, using an LDPC code, the encoded communication to obtain a communication, the LDPC code being associated with a base graph that is in accordance with a stability metric condition.

Some aspects described herein relate to an apparatus for wireless communication. The apparatus may include means for encoding, using an LDPC code, a communication to obtain an encoded communication, the LDPC code being associated with a base graph that is in accordance with a stability metric condition. The apparatus may include means for providing the encoded communication.

Aspects of the present disclosure may generally be implemented by or as a method, apparatus, system, computer program product, non-transitory computer-readable medium, user equipment, network node, wireless communication device, or processing system as substantially described in the Detailed Description with reference to, and as illustrated by, the accompanying drawings. Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 is a diagram illustrating an example of a wireless communication network.

FIG. 2 is a diagram illustrating an example of communication using low-density parity check (LDPC) codes.

FIGS. 3A and 3B are diagrams illustrating an example of an LDPC base graph matrix and an LDPC base graph.

FIG. 4 is a diagram illustrating an example of a parity-check matrix associated with an LDPC code.

FIG. 5 is a diagram illustrating an example of a base graph that supports fast converging LDPC techniques.

FIG. 6 is a diagram illustrating an example of mapping coded bits.

FIG. 7 is a diagram illustrating an example associated with a rank condition for LDPC codes.

FIG. 8 is a diagram illustrating an example of a base graph matrix that satisfies a check degree condition for LDPC codes.

FIG. 9 is a diagram illustrating an example of an optimized row order of a base graph matrix for LDPC codes.

FIGS. 10A and 10B are diagrams illustrating an example of a base graph matrix that satisfies a degree-2 condition for LDPC codes.

FIG. 11 is a diagram illustrating an example process performed, for example, at a wireless communication device or an apparatus of a wireless communication device.

FIG. 12 is a diagram illustrating an example process performed, for example, at a wireless communication device or an apparatus of a wireless communication device.

FIG. 13 is a diagram illustrating an example process performed, for example, at a wireless communication device or an apparatus of a wireless communication device.

FIG. 14 is a diagram illustrating an example process performed, for example, at a wireless communication device or an apparatus of a wireless communication device.

FIG. 15 is a diagram of an example apparatus for wireless communication.

FIG. 16 is a diagram illustrating an example of a hardware implementation for an apparatus employing a processing system.

FIG. 17 is a diagram illustrating an example of an implementation of code and circuitry for an apparatus.

FIG. 18 is a diagram of an example apparatus for wireless communication.

FIG. 19 is a diagram illustrating an example of a hardware implementation for an apparatus employing a processing system.

FIG. 20 is a diagram illustrating an example of an implementation of code and circuitry for an apparatus.

### DETAILED DESCRIPTION

In some examples, to support use cases that may demand high data rates, high reliability, low latency, or low power consumption, channel coding may be used in a wireless communication system to ensure reliable and efficient communication. For example, channel coding may involve an encoding operation performed at a transmitter to add redundancy to transmitted data, and a decoding operation performed at a receiver where the additional redundancy is used to detect or correct errors that may occur during transmission or reception. For example, because wireless communication channels may be noisy or unreliable, data can be corrupted during transmission due to one or more factors, such as noise, interference, or channel fading, among other examples. When errors in transmitted data cannot be corrected at the receiver, the transmitted data may be lost or retransmissions may be performed to provide the correct data to the receiver. Accordingly, because lost data reduces reliability and retransmissions increase latency and power consumption, channel coding techniques are used in wireless communication systems to ensure that received data is the same as transmitted data. For example, channel coding techniques may use polar codes, Reed-Muller codes, repetition codes, or simplex codes for control channels or other channels with low to moderate payload sizes. Channel coding techniques may use turbo codes or low density parity check (LDPC) codes for data channels or other channels that tend to have relatively larger payload sizes.

In this way, channel coding techniques may offer various performance improvements in wireless communication systems. For example, channel coding techniques provide error detection and error correction capabilities that may increase a likelihood that transmitted data is reliably received despite noise, interference, or fading conditions that may be present in a wireless channel. In addition, channel coding may reduce an error rate and increase reliability for wireless transmission, which may mitigate errors, reduce retransmissions, and improve overall throughput. Furthermore, although encoding and decoding operations may add some processing delay, efficient channel coding schemes may reduce the processing delay and the improved error detection and correction capabilities may reduce retransmissions, which reduces overall latency. Channel coding techniques may also extend wireless coverage because a transmitter may transmit data in a reliable manner over a longer distance or in a challenging radio environment, may improve spectral efficiency by minimizing the impact that errors have on the use of available frequency spectrum, or may improve energy efficiency at network nodes and user devices by supporting efficient encoding or decoding schemes or reducing retransmissions, among other examples.

LDPC codes are linear block codes that may be used to provide forward error correction capabilities in a communication system with a performance that approaches channel capacity. The performance may be achieved under an iterative belief propagation decoding scheme, also known as message-passing decoding, which has a linear complexity associated with an LDPC code block length. In particular, LDPC codes may be defined or represented according to a sparse parity check matrix (PCM) that typically has a low density of entries with a value of one. For example, the PCM may be “sparse” in that the PCM may include a relatively high quantity of entries with a value of zero. From a transmitter perspective, the transmitter (or LDPC encoder) may multiply one or more systematic bits by a PCM to generate a code block (or codeword). A codeword may include one or more systematic bits and one or more parity bits. Systematic bits may sometimes be referred to as information bits. The sparse PCM generally includes a systematic matrix and a parity matrix. The systematic matrix may be a portion of the PCM or a base graph matrix that includes information used to encode systematic bits of a communication. The parity matrix may be inverted to compute a parity vector used to encode an LDPC code. In some cases, an LDPC code may be quasi-cyclic. For example, a quasi-cyclic LDPC (QC-LDPC) code may be associated with a base graph and lifting values that provide a compact PCM representation, which enables efficient encoding and high parallelism in a decoder architecture.

The structure of a QC-LDPC code may be defined by a base graph and a lifting operation that transforms the base graph into a larger, more complex graph suitable for practical use. The base graph may be a graph that is used as the basis for constructing the larger graph, which may be a PCM for the LDPC code. The base graph may represent one or more macroscopic properties of the LDPC code, such as a signal-to-noise ratio (SNR) threshold required to achieve a given error rate. The base graph may indicate connectivity between variable nodes and check nodes. A variable node may represent one or more codeword bits, which may include systematic bits or parity bits. A check node may represent one or more parity constraints. The base graph may be represented as a base graph matrix in which columns of the base graph matrix represent respective variable nodes and rows of the base graph matrix represent respective check nodes. An entry in the base graph matrix with a value of one may indicate that a variable node is connected to a check node in the base graph, where the variable node is associated with the column of the entry and the check node is associated with the row of the entry. A “connection” between a variable node and a check node may also be referred to as an “edge.” A connection between a variable node and a check node in an LDPC code represents a parity-check constraint, indicating that the value of the variable node contributes to the parity-check equation defined by the check node.

The lifting operation may include expanding the base graph by a factor, sometimes referred to as a “lift value.” The lifting operation may result in a lifted graph or PCM, which may be used in the encoding and decoding processes. As part of the lifting operation, each entry in the base graph may be replaced by a circulant matrix. The circulant matrix may be an identity matrix that is cyclically shifted by a given cyclic shift. The identify matrix may have a size of Z×Z, where Z is the lift value. The lifting operation may preserve the degree distribution for each coded bit. Each variable node in the base graph may be associated with Z coded bits from the LDPC code. A “degree” of a variable node may be a quantity of check nodes that the variable node is connected to in the base graph.

In some examples, the LDPC code may be a systematic LDPC code in which the coded bits generated using the LDPC code include the original information bits followed by additional parity bits. In this structure, the information bits may be transmitted in their original form, making it easier for the receiver to obtain the original data directly if no errors occur. The parity bits may be generated through linear combinations of the information bits based on the PCM (or lifted graph) of the LDPC code. This systematic arrangement may simplify the encoding process and may enable more efficient error detection and correction during the decoding process, because the receiver can directly verify the integrity of the information bits against the parity bits.

In some examples, the encoding process may include a transmitter mapping one or more coded bits to a constellation symbol, sometimes referred to as a modulated symbol, using a mapping scheme. In the context of LDPC codes, a mapping scheme may refer to a method or technique used to assign coded bits to specific positions within modulation constellation symbols. “Modulation constellation symbol” refers to a point in a signal space diagram representing a specific combination of amplitude and phase used in digital modulation schemes to transmit data over communication channels. In some examples, the mapping scheme may include a systematic bit priority mapping (SBPM) scheme. SBPM may be a technique to map systematic bits of a communication to the most significant bits of each modulated symbol of the communication. This increases reliability due to an increased likelihood of correct demodulation of the systematic bits because the most significant bits (e.g., the most significant bit, or one or more most significant bits) of the modulated symbol have increased protection against errors as compared to the least significant bits (e.g., the least significant bit, or one or more least significant bits) of the modulated symbol when using conventional modulation constellations, such as phase-shift keying (PSK) or quadrature amplitude modulation (QAM). For example, even if a receiver incorrectly demodulates a modulated symbol, that incorrect demodulation is likely to correspond to a constellation symbol, in a constellation diagram for the conventional modulation scheme, that is near the correct constellation symbol and that has one or more most significant bits in common with the correct constellation symbol. SBPM may be referred to as a bit-to-modulation mapping technique. For example, SBPM may be a technique for mapping coded bits to modulation constellation symbols for over-the-air transmission.

In some aspects, mapping coded bits to constellation symbols (e.g., SBPM mapping) may be performed using a technique called write by row, read by column. Using this technique, bits may be obtained from a circular buffer as part of a rate matching process, with a starting bit determined based at least in part on a redundancy version, of the communication, to be transmitted. As the bits are obtained, those bits may be written to blocks across a first row, where each bit is placed in a different column corresponding to a different constellation symbol. After the first row is filled, bits may be written to blocks across a second row, and so on. The starting bit and a set of subsequent bits of the circular buffer may be systematic bits, and may be followed by parity bits. As a result, the first one or more rows may include systematic bits, and the last one or more rows may include parity bits.

Because the first row(s) correspond to more significant bits (e.g., most significant bits (MSBs)) of the constellation symbol and the last row(s) correspond to less significant bits (e.g., least significant bits (LSBs)) of the constellation symbol, this technique may map systematic bits (e.g., some, most, or all of the systematic bits, depending on a starting bit in the circular buffer) to the MSB(s) of the constellation symbol, thereby increasing reliability. As an example, an SBPM scheme may enable a transmitter to map the systematic portion of coded bits (e.g., LDPC coded bits) to the MSB of a modulation constellation, and to map the non-systematic portion to the LSB of the modulation constellation. Without applying SBPM, each variable node in the base graph may experience, on average, the same channel conditions or reliabilities. As a result of applying SBPM, copies of the same variable node in a base graph may be associated with similar channel reliabilities, and different variable nodes in the base graph may experience different channel reliabilities. By improving a likelihood of copies of the same variable node in a base graph being associated with similar channel reliabilities (e.g., by mapping them consistently to the MSB or LSB, for example), the SBPM scheme may improve a decoding threshold for a channel coding scheme, such as the QC-LDPC coding scheme described herein.

In some examples, a base graph may include one or more punctured nodes. “Punctured node” refers to a variable node whose associated coded bits are not transmitted by a transmitter. The coded bits associated with the punctured node may be inferred by a receiver using received coded bits during the decoding process. As a result, having the one or more punctured nodes may reduce the code rate of the LDPC code while maintaining error correction capabilities. In some examples, the one or more punctured nodes having a larger degree may improve asymptotic performance for the LDPC codes. “Asymptotic performance” may refer to the behavior and effectiveness of an error-correcting code, such as the LDPC code, as the block length (the number of bits in a codeword) approaches infinity, indicating how well the LDPC code performs in terms of error correction and reliability under long-term conditions. To increase the degree of the one or more punctured nodes, some base graphs may include two or more punctured nodes, such as the base graph 1 (BG1) defined, or otherwise fixed, by the 3GPP.

However, having multiple punctured nodes in the base graph may increase a convergence time associated with the decoding process. For example, having multiple punctured nodes in the base graph may increase the amount of unknown information at the receiver, because the transmitter does not transmit the coded bits associated with the multiple punctured nodes. Therefore, the receiver may perform a relatively high quantity of decoding iterations in order to reach a reasonable reliability level for the coded bits associated with the multiple punctured nodes. The relatively high quantity of decoding iterations may increase the convergence time associated with the decoding process, or consume processing resources associated with the receiver performing the decoding process, among other examples.

To improve performance of LDPC codes, one or more base graphs with advanced features may be introduced. For example, a base graph may include a single punctured node. For example, the base graph may include only one punctured node. The base graph including a single punctured node may reduce the convergence time associated with the decoding process because there may be less unknown information at the receiver. In some examples, the single punctured node may be connected to a given check node via multiple connections or edges. The multiple connections or edges may include multiple connections or edges between a given check node and the single punctured node. This type of connection may be referred to as a parallel edge, a double edge, or a multi-edge, among other examples. For example, this type of connection may be represented in a base graph entry by a value of two or higher to indicate a quantity of connections between the punctured node and the given check node. Having the single punctured node connected to a given check node via multiple connections or edges may increase the degree of the punctured node, thereby improving the asymptotic performance for the LDPC codes. However, having multiple connections or edges for the single punctured node may result in an increased quantity of dependencies between the single punctured node and check nodes included in the base graph. This may increase decoding complexity for the LDPC code.

As base graphs with advanced features are introduced, the design and optimization of base graphs for LDPC codes may consider multiple factors, such as the balance between convergence speed and asymptotic performance, the stability metrics across different modulation schemes, or the efficient handling of punctured nodes. For example, as new features are included in a base graph to improve performance, there may be a risk that the new features reduce the stability or error floor of the LDPC code. The error floor may be a plateau in an error rate performance curve, where further increases in SNR result in minimal improvements in error rate reduction. Therefore, there is a risk that new features for a base graph may improve an achievable performance for the LDPC code, but may also reduce the stability or error floor of the LDPC code. This may result in increased error rates in some scenarios (such as higher SNR scenarios), thereby reducing the overall reliability and robustness of the wireless communication system.

Various aspects relate generally to one or more conditions for optimizing base graphs for LDPC codes. In some aspects, the one or more conditions may include a check degree condition for a base graph that includes a single puncture node. The “check degree condition” may refer to a condition on a degree or connection type for the single puncture node. For example, the check degree condition may indicate that one or more check nodes are to be connected to the single punctured node via one or more respective single edges. In some aspects, the base graph may include one or more other check nodes connected to the single punctured node via respective multiple edges. For example, a given check node, from the one or more other check nodes, may be connected to the single punctured node via multiple edges. In some aspects, the check degree condition may indicate that the one or more check nodes that are connected to the single punctured node via one or more respective single edges are to have a lower degree than the one or more other check nodes connected to the single punctured node via respective multiple edges.

In some aspects, a wireless communication device that receives an encoded communication that is encoded using an LDPC code that is based on the base graph may decode the encoded communication using a layered (or sequential) decoding process. For example, the wireless communication device may first decode the one or more check nodes that are connected to the single punctured node via one or more respective single edges. Second, after decoding the one or more check nodes that are connected to the single punctured node via one or more respective single edges, the wireless communication device may decode the one or more other check nodes connected to the single punctured node via respective multiple edges.

Additionally, or alternatively, the one or more conditions may include a stability metric condition. The “stability metric condition” may refer to a condition indicating a threshold or level that a stability metric associated with the base graph is to meet. “Stability metric,” in the context of LDPC codes, may be a quantitative measure used to assess the robustness of the iterative decoding process against noise and errors. The stability metric may be indicative of the propensity of a decoding operation to converge to a correct solution as the quantity of iterations increases, such as in the presence of noise. A lower stability metric may indicate a more stable and reliable decoding operation, indicating that the LDPC code can effectively correct errors with fewer iterations, thereby minimizing the risk of persistent errors and improving the overall error floor performance. The stability metric condition may indicate that a stability metric of a core portion of the base graph is to satisfy a threshold. “Core portion” or simply “core” of the base graph may refer to a portion of the base graph that defines the highest-rate portion of the code, such as a portion of the base graph that results in a highest ratio of information bits to total bits transmitted. The core portion may include a systematic portion and a core parity portion. The “systematic” portion may include one or more variable nodes to which information bits are mapped, such as one or more variable nodes that result in a reproduction of the information bits. The “core parity” portion refers to one or more variable nodes that produce one or more parity bits that are necessary for error correction.

Additionally, or alternatively, the one or more conditions may include a degree-two condition. The “degree-two” condition may refer to a condition on an allowable quantity of variable nodes having a degree of two in the base graph, such as in the core portion of the base graph. The degree-two condition may indicate that a quantity of variable nodes having a degree of two in the core portion is to satisfy a threshold. In some examples, the degree-two condition may be indicated by the stability metric condition. In other examples, the degree-two condition may be a separate condition for the base graph.

In some aspects, by wireless communication devices communicating one or more encoded communications that use an LDPC code that is based on a base graph that satisfies the one or more conditions, an encoding operation and a decoding operation for the one or more encoded communications may be optimized to balance performance, fast convergence, and stability, among other examples. This may improve the overall decoding and encoding efficiency, improve reliability, or improve the robustness for encoded communications communicated in a wireless communication system. In some aspects, by the base graph satisfying the check degree condition, a convergence time for the decoding operation may be reduced. For example, ensuring that at least one check node is connected to a punctured node via a single edge may enable a wireless communication device to start fast decoding because an initial decoding operation may be simplified. In LDPC codes, decoding may involve iterative message passing between variable nodes and check nodes. When a punctured node is connected to a check node with a single edge, the check node has fewer dependencies on other variable nodes, enabling the wireless communication device to resolve a value of the check node quickly and reliably. This initial resolution provides a foundation for subsequent decoding iterations, as the resolved check node can immediately contribute reliable information to neighboring nodes. As a result, the decoding operation at the wireless communication device may begin with a straightforward and rapid update, thereby reducing the overall number of iterations needed to achieve successful decoding, thereby enhancing the efficiency and speed of the decoding operation.

In some aspects, by the one or more check nodes that are connected to the single punctured node via one or more respective single edges having a lower degree than the one or more other check nodes connected to the single punctured node via respective multiple edges, the wireless communication device may perform the decoding operation with faster convergence. For example, check nodes with lower degrees may have fewer dependencies, enabling the wireless communication device to resolve their values more quickly and reliably using the layered or sequential decoding operation, which can enable the wireless communication device to initiate the decoding process more effectively. The early resolution of check node values may enable the wireless communication device to propagate reliable information throughout other check nodes or variable nodes, thereby reducing the quantity of iterations required for successful decoding. Additionally, the one or more check nodes that are connected to the single punctured node via one or more respective single edges having lower degrees may enhance the overall decoding efficiency by minimizing computational complexity, as fewer iterations in the decoding operation may reduce processing time and energy consumption by the wireless communication device.

In some aspects, by the wireless communication devices communicating one or more encoded communications that use an LDPC code that is based on a base graph that satisfies the stability metric condition, an error floor of the LDPC code may be improved while also maintaining higher performance for the LDPC code. For example, the wireless communication devices ensuring that the base graph satisfies the stability metric condition may reduce the likelihood of persistent errors that occur in some scenarios (such as at higher SNRs), thereby lowering the error floor. This may enable the base graph to have an optimized balance between the quantity of variable nodes having a degree of two (for improved SNR thresholds for some block error rate (BLER) targets) and a placement of the variable nodes having a degree of two within the base graph (for an improved error floor). As a result, the wireless communication devices may achieve robust error correction capabilities without sacrificing throughput or efficiency, allowing for reliable communication even in challenging conditions. Moreover, maintaining a lower error floor while achieving high performance ensures that the wireless communication system can support higher data rates and more demanding applications, thereby enhancing the overall reliability and effectiveness of the wireless communication network.

5G New Radio (NR) may support enhanced mobile broadband (eMBB) access, Internet of Things (IoT) networks or reduced capability (RedCap) device deployments, ultra-reliable low-latency communication (URLLC) applications, or massive machine-type communication (mMTC), among other examples. To support these and other target verticals, a wireless communication system may be designed to implement a modularized functional infrastructure, a disaggregated and service-based network architecture, network function virtualization, network slicing, multi-access edge computing, millimeter wave (mmWave) technologies including massive multiple-input multiple-output (MIMO), beamforming, IoT device or RedCap device connectivity and management, industrial connectivity, licensed and unlicensed spectrum access, sidelink and other device-to-device direct communication (for example, cellular vehicle-to-everything (CV2X) communication), frequency spectrum expansion, overlapping spectrum use, small cell deployments, non-terrestrial network (NTN) deployments, device aggregation, advanced duplex communication (for example, sub-band full-duplex (SBFD)), multiple-subscriber implementations, high-precision positioning, radio frequency (RF) sensing, network energy savings (NES), low-power signaling and radios, or artificial intelligence or machine learning (AI/ML), among other examples.

The foregoing and other technological improvements may support use cases, such as wireless fronthauls, wireless midhauls, wireless backhauls, wireless data centers, extended reality (XR) and metaverse applications, meta services for supporting vehicle connectivity, holographic and mixed reality communication, autonomous and collaborative robots, vehicle platooning and cooperative maneuvering, sensing networks, gesture monitoring, human-brain interfacing, digital twin applications, asset management, and universal coverage applications using non-terrestrial or aerial platforms, among other examples.

The methods, operations, apparatuses, and techniques described herein may enable one or more of the foregoing technologies or new technologies or support one or more of the foregoing use cases or new use cases.

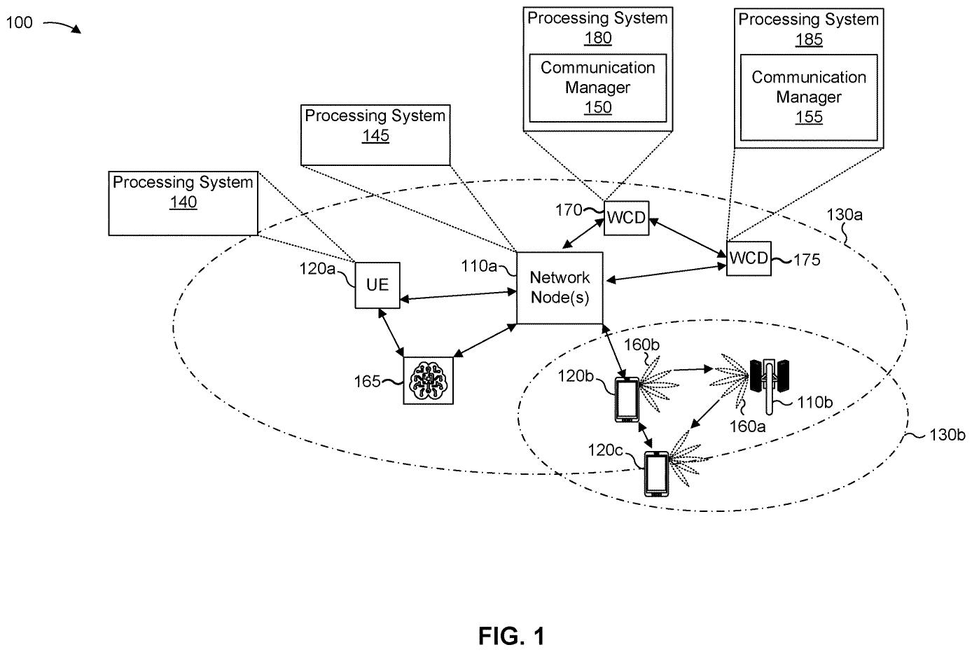

FIG. 1 is a diagram illustrating an example of a wireless communication network 100. The wireless communication network 100 may be or may include elements of a 5G network or a 6G network, among other examples. The wireless communication network 100 may include multiple network nodes 110. For example, in FIG. 1, the wireless communication network 100 includes multiple network nodes 110, including a network node 110a and a network node 110b (each of which also may be referred to herein simply as a “network node 110”). The network nodes 110 may support communications with multiple user equipments (UEs) 120. For example, in FIG. 1, the network nodes 110 support communication with a UE 120a, a UE 120b, and a UE 120c (each of which also may be referred to herein simply as a “UE 120”). In some examples, a UE 120 also may communicate with other UEs 120 and a network node 110 also may communicate with a core network and with other network nodes 110.

The network nodes 110 and the UEs 120 of the wireless communication network 100 communicate using the electromagnetic spectrum, which may be subdivided into various licensed or unlicensed operating bands, frequency ranges, component carriers, or channels that define associated frequencies available for communications. In some examples, each of the network nodes 110 and the UEs 120 may communicate using one or multiple component carriers in one or more operating bands or ranges. Typically, various operating bands are defined as frequency range designations FR1 (410 MHz through 7.125 GHz), FR2 (24.25 GHz through 52.6 GHz), FR3 (7.125 GHz through 24.25 GHz), FR4a or FR4-1 (52.6 GHz through 71 GHz), FR4 (52.6 GHz through 114.25 GHz), and FR5 (114.25 GHz through 300 GHz). Although a portion of FR1 is greater than 6 GHz, FR1 is often referred to (interchangeably) as a “sub-6 GHz” band in some documents and articles. Similarly, FR2 is often referred to (interchangeably) as a “millimeter wave” band in some documents and articles.

A network node 110 or a UE 120 may include one or more devices, components, or systems that enable communication with other devices, components, or systems of the wireless communication network 100. For example, a UE 120 and a network node 110 may each include one or more chips, system-on-chips (SoCs), chipsets, packages, or devices that individually or collectively constitute or comprise a processing system. As shown in FIG. 1, each UE 120 includes a processing system 140 and each network node 110 includes a processing system 145. A processing system (for example, the processing system 140 or the processing system 145) includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASICs), programmable logic devices (PLDs), or other discrete gate or transistor logic or circuitry (any one or more of which may be generally referred to herein individually as a “processor” or collectively as “the processor” or “the processor circuitry”). Such processors may be individually or collectively configurable or configured to perform various functions or operations described herein. A group of processors collectively configurable or configured to perform a set of functions may include a first processor configurable or configured to perform a first function of the set and a second processor configurable or configured to perform a second function of the set. In some other examples, each of a group of processors may be configurable or configured to perform a same set of functions.

The processing system 140 and the processing system 145 may each include memory circuitry in the form of one or multiple memory devices, memory blocks, memory elements, or other discrete gate or transistor logic or circuitry, each of which may include or implement tangible storage media, such as random-access memory, or read-only memory, or combinations thereof (any one or more of which may be generally referred to herein individually as a “memory” or collectively as “the memory” or “the memory circuitry”). One or more of the memories may be coupled (for example, operatively coupled, communicatively coupled, electronically coupled, or electrically coupled) with one or more of the processors. One or more of the memories may individually or collectively store processor-executable code or instructions (such as software) (for example, which may be referred to as “one or more code-storing memories” or “code-storing memory circuitry”). For example, “code-storing memory” or “code-storing memory circuitry” refers to memory (or memory circuitry) that is configured to store processor-executable code or instructions. The processor-executable code or instructions, when executed by one or more of the processors, may configure one or more of the processors (or processing circuitry) to perform various functions or operations described herein. Additionally, or alternatively, in some examples, one or more of the processors may be configured to perform various functions or operations described herein without requiring configuration by software. Software shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise.

The processing system 140 and the processing system 145 may each include or be coupled with one or more modems (such as a cellular (for example, a 5G or 6G compliant) modem). In some examples, one or more processors of the processing system 140 or the processing system 145 may include or implement one or more of the modems. The processing system 140 and the processing system 145 also may include or be coupled with multiple radios (collectively “the radio”), multiple RF chains, or multiple transceivers, each of which may in turn be coupled with one or more of multiple antennas. In some examples, one or more processors of the processing system 140 or the processing system 145 may include or implement one or more of the radios, RF chains, or transceivers. An RF chain may include one or more filters, mixers, oscillators, amplifiers, analog-to-digital converters (ADCs), or other devices that convert between an analog signal (such as for transmission or reception via an air interface) and a digital signal (such as for processing by the processing system 140 or by the processing system 145).

A network node 110 and a UE 120 may each include one or multiple antennas or antenna arrays. Typical network nodes 110 and UEs 120 may include multiple antennas, which may be organized or structured into one or more antenna panels, one or more antenna groups, one or more sets of antenna elements, or one or more antenna arrays, among other examples. As used herein, the term “antenna” can refer to one or more antennas, one or more antenna panels, one or more antenna groups, one or more sets of antenna elements, or one or more antenna arrays. The term “antenna panel” can refer to a group of antennas (such as antenna elements) arranged in an array or panel, which may facilitate beamforming by manipulating parameters associated with the group of antennas. The term “antenna module” may refer to circuitry including one or more antennas as well as one or more other components (such as filters, amplifiers, or processors) associated with integrating the antenna module into a wireless communication device, such as the network node 110 and the UE 120.

A network node 110 may be, may include, or also may be referred to as an NR network node, a 5G network node, a 6G network node, a Node B, a gNB, an access point (AP), a transmission reception point (TRP), a network entity, a network element, a network equipment, or another type of device, component, or system included in a radio access network (RAN). In various deployments, a network node 110 may be implemented as a single physical node (for example, a single physical structure) or may be implemented as two or more physical nodes (for example, two or more distinct physical structures). For example, a network node 110 may be a device or system that implements a part of a radio protocol stack, a device or system that implements a full radio protocol stack (such as a full gNB protocol stack), or a collection of devices or systems that collectively implement the full radio protocol stack. For example, and as shown, a network node 110 may be an aggregated network node having an aggregated architecture, meaning that the network node 110 may implement a full radio protocol stack that is physically and logically integrated within a single physical structure in the wireless communication network 100. For example, an aggregated network node 110 may include a single standalone base station or a single TRP that operates with a full radio protocol stack to enable or facilitate communication between a UE 120 and a core network of the wireless communication network 100.

Alternatively, a network node 110 may be a disaggregated network node 110 (sometimes referred to as a disaggregated base station), having a disaggregated architecture, meaning that the network node 110 may operate with a radio protocol stack that is physically distributed or logically distributed among two or more nodes in the same geographic location or in different geographic locations. In some deployments, disaggregated network nodes 110 may be used in an integrated access and backhaul (IAB) network, in an open radio access network (O-RAN) (such as a network configuration in compliance with the O-RAN Alliance), or in a virtualized radio access network (vRAN), also known as a cloud radio access network (C-RAN), to facilitate scaling by separating network functionality into multiple units or modules that can be individually deployed.

The disaggregated network nodes 110 of the wireless communication network 100 may include one or more central units (CUs), one or more distributed units (DUs), and one or more radio units (RUs). A CU may host one or more higher layers, such as a radio resource control (RRC) layer, a packet data convergence protocol (PDCP) layer, and a service data adaptation protocol (SDAP) layer, among other examples. A CU can communicate with a core network either directly (for example, via a backhaul link) or indirectly (for example, via one or more disaggregated control units, such as a non-real-time (Non-RT) RAN intelligent controller (RIC) associated with a Service Management and Orchestration (SMO) framework or a near-real-time (Near-RT) RIC). A DU may host one or more of a radio link control (RLC) layer, a medium access control (MAC) layer, or one or more higher physical (PHY) layers depending, at least in part, on a functional split, such as a functional split defined by the 3GPP. In some examples, a DU also may host a lower PHY layer that is configured to perform functions, such as a fast Fourier transform (FFT), an inverse FFT (IFFT), beamforming, or physical random access channel (PRACH) extraction and filtering, among other examples. An RU may perform RF processing functions or lower PHY layer functions, such as an FFT, an IFFT, beamforming, or PRACH extraction and filtering, among other examples, according to a functional split, such as a lower layer split (LLS). In such an architecture, each RU can be operated to handle over the air (OTA) communication with one or more UEs 120. A CU may communicate with one or more DUs via respective midhaul links, such as via F1 interfaces. Each of the DUs may communicate with one or more RUs via respective fronthaul links. Each of the RUs may communicate with one or more UEs 120 via respective RF access links. In some deployments, a UE 120 may be simultaneously served by multiple RUs.

In some examples, a single network node 110 may include a combination of one or more CUs, one or more DUs, or one or more RUs. In some examples, a CU, a DU, or an RU may be implemented as a virtual unit, such as a virtual central unit (VCU), a virtual distributed unit (VDU), or a virtual radio unit (VRU), among other examples, which may be implemented as a virtual network function, such as in a cloud deployment (for example, an open cloud (O-Cloud) platform). An SMO framework may support RAN deployment and provisioning of non-virtualized and virtualized network elements.

In some examples, the wireless communication network 100 may be a heterogeneous network that includes network nodes 110 of various types. Different types of network nodes 110 may generally operate on the same or different operating bands, transmit at different power levels, or serve different coverage areas, each of which may be referred to as or associated with a particular cell 130 (for example, a cell 130a and a cell 130b).

The UEs 120 may be physically dispersed throughout the coverage area of the wireless communication network 100, and each UE 120 may be stationary or mobile. A UE 120 may be, may include, or also may be referred to as an access terminal, a mobile station, a client device, or a subscriber unit. A UE 120 may be, include, or be coupled with a cellular phone (for example, a smart phone), a personal digital assistant (PDA), a wireless modem, a wireless communication device, a handheld device, a laptop computer, a cordless phone, a wireless local loop (WLL) station, a tablet, a camera, a netbook, a smartbook, an ultrabook, a medical device, a biometric device, a wearable device (for example, a smart watch, smart clothing, smart glasses, a smart wristband, or smart jewelry), a gaming device, an entertainment device (for example, a music device, a video device, or a satellite radio), an XR device, a vehicular component or sensor, a smart meter or sensor, industrial manufacturing equipment, a Global Navigation Satellite System (GNSS) device (such as a Global Positioning System device or another type of positioning device), an artificially intelligent robot or other device implementing artificial intelligence, a UE function of a network node, or any other suitable device or function that may communicate in the wireless communication network 100.

Some UEs 120 may be classified according to different categories in association with different complexities or different capabilities. UEs 120 in a first category may be associated with relatively low complexity or cost such as NB-IoT devices or eMTC UEs. UEs 120 in a second category may include higher complexity or cost devices, such as mission-critical IoT devices, baseline UEs, high-tier UEs, advanced UEs, full-capability UEs, or premium UEs that are capable of URLLC, eMBB, or precise positioning in the wireless communication network 100. A third category of UEs 120 may have mid-tier complexity or capabilities (for example, capabilities between that of the UEs 120 of the first category and the UEs 120 of the second category). A UE 120 of the third category may be referred to as a reduced capability UE (“RedCap UE”), a mid-tier UE, an NR-Light UE, or an NR-Lite UE, among other examples.

In some examples, a network node 110 may be, may include, or may operate as an RU, a TRP, or a base station that communicates with one or more UEs 120 via a radio access link (which may be referred to as a “Uu” link). The radio access link may include a downlink and an uplink. “Downlink” (or “DL”) refers to a communication direction from a network node 110 to a UE 120, and “uplink” (or “UL”) refers to a communication direction from a UE 120 to a network node 110. Downlink and uplink resources may include time domain resources (for example, frames, subframes, slots, and symbols), frequency domain resources (for example, frequency bands, component carriers (CCs), subcarriers, resource blocks, and resource elements), and spatial domain resources (for example, particular transmit directions or beams).

Frequency domain resources may be subdivided into bandwidth parts (BWPs). A BWP may be a block of frequency domain resources (for example, a continuous set of resource blocks (RBs) within a full component carrier bandwidth) that may be configured at a UE-specific level. A UE 120 may be configured with both an uplink BWP and a downlink BWP (which may be the same or different). Each BWP may be associated with its own numerology (indicating a sub-carrier spacing (SCS) and cyclic prefix (CP)). A BWP may be dynamically configured or activated (for example, by a network node 110 transmitting a downlink control information (DCI) configuration to the one or more UEs 120) or reconfigured (for example, in real-time or near-real-time) according to changing network conditions in the wireless communication network 100 or specific requirements of one or more UEs 120. An active BWP defines the operating bandwidth of the UE 120 within the operating bandwidth of the serving cell.

As used herein, a downlink signal may be or include a reference signal, control information, or data. For example, downlink reference signals include a primary synchronization signal (PSS), a secondary SS (SSS), an SS block (SSB) (for example, that includes a PSS, an SSS, and a physical broadcast channel (PBCH)), a demodulation reference signal (DMRS), a phase tracking reference signal (PTRS), a tracking reference signal (TRS), and a channel state information (CSI) reference signal (CSI-RS), among other examples. A downlink signal carrying control information or data may be transmitted via a downlink channel. Downlink channels may include one or more control channels for transmitting control information and one or more data channels for transmitting data. Downlink reference signals may be transmitted in addition to, or multiplexed with, downlink control channel communications or downlink data channel communications. A downlink control channel may be specifically used to transmit DCI from a network node 110 to a UE 120. DCI generally contains the information the UE 120 needs to identify RBs in a subsequent subframe and how to decode them, including a modulation and coding scheme (MCS) or redundancy version parameters. Different DCI formats carry different information, such as scheduling information in the form of downlink or uplink grants, slot format indicators (SFIs), preemption indicators (PIs), transmit power control (TPC) commands, hybrid automatic repeat request (HARQ) information, new data indicators (NDIs), among other examples. A downlink data channel may be used to transmit downlink data (for example, user data associated with a UE 120) from a network node 110 to a UE 120. Downlink control channels may include physical downlink control channels (PDCCHs), and downlink data channels may include physical downlink shared channels (PDSCHs). Control information or data communications may be transmitted on a PDCCH and PDSCH, respectively. For example, a PDCCH can carry DCI, while a PDSCH can carry a MAC control element (MAC-CE), an RRC message, or user data, among other examples. Each PDSCH may carry one or more transport blocks (TBs) of data.

As used herein, an uplink signal may include a reference signal, control information, or data. For example, uplink reference signals include a sounding reference signal (SRS), a PTRS, and a DMRS, among other examples. An uplink signal carrying control information or data may be transmitted via an uplink channel. An uplink channel may include one or more control channels for transmitting control information and one or more data channels for transmitting data. Uplink reference signals may be transmitted in addition to, or multiplexed with, uplink control channel communications or uplink data channel communications. An uplink control channel may be specifically used to transmit uplink control information (UCI) from a UE 120 to a network node 110. An uplink data channel may be used to transmit uplink data (for example, user data associated with a UE 120) from a UE 120 to a network node 110. Uplink control channels may include physical uplink control channels (PUCCHs), and uplink data channels may include physical uplink shared channels (PUSCHs). Control information or data communications may be transmitted on a PUCCH and PUSCH, respectively. For example, a PUCCH can carry UCI, while a PUSCH can carry a MAC-CE, an RRC message, or user data, among other examples. UCI can include a scheduling request (SR), HARQ feedback information (for example, a HARQ acknowledgement (ACK) indication or a HARQ negative acknowledgement (NACK) indication), uplink power control information (for example, an uplink TPC parameter), or CSI, among other examples. CSI can include a channel quality indicator (CQI) (indicative of downlink channel conditions to facilitate selection of transmission parameters, such as an MCS, by a network node 110), a precoding matrix indicator (PMI), a CSI-RS resource indicator (CRI) (for example, indicative of a beam used to transmit a CSI-RS), an SS/PBCH resource block indicator (SSBRI) (for example, indicative of a beam used to transmit an SSB), a layer indicator (LI), a rank indicator (RI), or measurement information (for example, a layer 1 (L1)-reference signal received power (RSRP) parameter, a received signal strength indicator (RSSI) parameter, a reference signal received quality (RSRQ) parameter, among other examples) which can be used for beam management, among other examples. Each PUSCH may carry one or more TBs of data.

The information (for example, data, control information, or reference signal information) transmitted by a network node 110 to a UE 120, or vice versa, may be represented as a sequence of binary bits that are mapped (for example, modulated) to an analog signal waveform (for example, a discrete Fourier transform (DFT)-spread-orthogonal frequency division multiplexing (OFDM) (DFT-s-OFDM) waveform or a CP-OFDM waveform) that is transmitted by the network node 110 or UE 120 over a wireless communication channel. In some examples, the network node 110 or the UE 120 (for example, using the processing system 145 or the processing system 140, respectively) may select an MCS (for example, an order of QAM, such as 64-QAM, 128-QAM, or 256-QAM, among other examples) for a downlink signal or an uplink signal. For example, the network node 110 may select an MCS for a downlink signal in accordance with UCI received from the UE 120 or may transmit, to the UE 120, an indication of an MCS to be applied for an uplink signal.

A network node 110 or a UE 120 (such as by using the processing system 145 or the processing system 140, respectively, or one or more coupled modems) may perform signal processing on the information (such as filtering, amplification, modulation, digital-to-analog conversion, an IFFT operation, multiplexing, interleaving, mapping, or encoding, among other examples) to generate a processed signal in accordance with the selected MCS. In some examples, the network node 110 or the UE 120 (for example, using the processing system 145 or the processing system 140, respectively, or one or more coupled encoders or modems) may perform a channel coding operation or a forward error correction (FEC) operation to control errors in transmitted information. For example, the network node 110 or the UE 120 may perform an encoding operation to generate encoded information (such as by selectively introducing redundancy into the information, typically using an error correction code (ECC), such as a polar code or an LDPC code). The network node 110 or the UE 120 (for example, using the processing system 145 or one or more modems) may further perform spatial processing (for example, precoding) on the encoded information to generate one or more processed or precoded signals for downlink or uplink transmission, respectively. In some examples, the network node 110a or the UE 120a may perform codebook-based precoding or non-codebook-based precoding. Codebook-based precoding may involve selecting a precoder (for example, a precoding matrix) using a codebook. For example, the network node 110a may provide precoding information indicating which precoder, defined by the codebook, is to be used by the UE 120a. Non-codebook-based precoding may involve selecting or deriving a precoder based on, or otherwise associated with, one or more downlink or uplink signal measurements. The network node 110a or the UE 120a may transmit the processed downlink or uplink signals, respectively, via one or more antennas.

The network node 110a or the UE 120a may receive uplink signals or downlink signals, respectively, via one or more antennas. The network node 110a or the UE 120a (for example, using the processing system 145 or the processing system 140, respectively, or one or more coupled modems) may perform signal processing (for example, in accordance with the MCS) on the received uplink or downlink signals, respectively (such as filtering, amplification, demodulation, analog-to-digital conversion, an FFT operation, demultiplexing, deinterleaving, de-mapping, equalization, interference cancellation, or decoding, among other examples), to map the received signal(s) to a sequence of binary bits (for example, received information) that estimates the information transmitted by the network node 110 or the UE 120 via the downlink or uplink signals. The network node 110a or the UE 120a (for example, using the processing system 145 or the processing system 140, respectively, or a coupled decoder or one or more modems) may decode the received information (such as by using an ECC, a decoding operation, or an FEC operation) to detect errors or correct bit errors in the received information to generate decoded information. The decoded information may estimate the information transmitted via the downlink or uplink signals.

In some examples, a UE 120 and a network node 110 may perform MIMO communication. MIMO communication generally refers to transmitting or receiving multiple signals (such as multiple layers or multiple data streams) simultaneously over the same time and frequency resources. A network node 110 or a UE 120 may communicate using single-user MIMO or multi-user MIMO (MU-MIMO), the latter of which being used by a network node 110 to simultaneously transmit signals to multiple UEs 120. MIMO techniques may involve spatial multiplexing (multi-layer transmission) or beamforming. To implement beamforming, the amplitudes or phases of signals transmitted via antenna elements may be modulated and shifted relative to each other (such as by manipulating a phase shift, a phase offset, or an amplitude) to generate one or more beams. For example, a network node 110 may generate one or more beams 160a, and a UE 120 may generate one or more beams 160b. The term “beam” may refer to a directional transmission of a wireless signal toward a receiving device or otherwise in a desired direction, a directional reception of a wireless signal from a transmitting device or otherwise in a desired direction, a direction associated with such a directional transmission or directional reception, a set of directional resources associated with a signal transmission or signal reception (for example, an angle of arrival, a horizontal direction, or a vertical direction), or a set of parameters or resources associated with one or more aspects of a directional signal, among other examples.

In some examples, a network node 110 or a UE 120 may implement massive MIMO, which may be associated with an increased (for example, “massive”) quantity of antennas at the network node 110 or at the UE 120, such as in a network implementing mmWave technology, which enables more precise beamforming or reduced interference. In some examples, the wireless communication network 100 may implement multi-TRP (mTRP) operation (including redundant transmission or reception on multiple TRPs) or non-coherent joint transmission (NC-JT).

The network node 110 and the UE 120 may establish a communication link or beam pair, and otherwise increase reliability, throughput, signal strength, or other signal properties for MIMO communications, by performing beam management operations, such as an initial beam acquisition operation, a beam refinement operation, or a beam recovery operation. For example, an initial beam acquisition operation may involve the network node 110 transmitting signals (for example, SSBs or other signals) via respective beams (for example, of the beams 160 of the network node 110) and the UE 120 receiving and measuring the signal(s) via respective beams of multiple beams (for example, from the beams 160 of the UE 120) to identify a best beam (or beam pair) for communication between the UE 120 and the network node 110. A beam refinement operation may involve a first device (for example, the UE 120 or the network node 110) transmitting signal(s) via a subset of beams (for example, identified based on, or otherwise associated with, measurements reported as part of one or more other beam management operations). A second device (for example, the network node 110 or the UE 120) may receive the signal(s) via a single beam (for example, to identify the best beam for communication from the subset of beams). The beam(s) may be identified or defined via one or more spatial parameters, such as a transmission configuration indicator (TCI) state or a quasi co-location (QCL) parameter, among other examples.

Some aspects and techniques as described herein may be implemented, at least in part, using an artificial intelligence (AI) program (for example, referred to herein as an “AI/ML model”), such as a program that includes a machine learning (ML) model or an artificial neural network (ANN) model. The AI/ML model may be deployed at one or more devices 165 (for example, one or more network nodes 110, one or more UEs 120, one or more servers, or one or more components of a cloud computing network, among other examples). For example, in a deployment in which AI/ML functionality is performed independently at a device 165, sometimes referred to as “overlay AI/ML,” the AI/ML model (or an instance or portion of the AI/ML model) may be deployed at a UE 120 (for example, by the processing system 140), a network node 110 (for example, by the processing system 145), one or more servers, or one or more components of a cloud computing network, among other examples. Additionally, or alternatively, in a deployment where AI/ML functionality is coordinated between different devices 165, sometimes referred to as “coordinated AI/ML,” or performed at all device and network layers, sometimes referred to as “native AI/ML,” the AI/ML model (or an instance of the AI/ML model) may be deployed at multiple devices 165 (for example, a first portion of the AI/ML model may be deployed at a UE 120 and a second portion of the AI/ML model may be deployed at a network node 110). In other examples of coordinated AI/ML or native AI/ML, a first AI/ML model may be deployed at a UE 120 and a second AI/ML model may be deployed at a network node 110. The AI/ML model(s) may be configured to enhance various aspects of the wireless communication network 100 (for example, to increase privacy, reliability, or efficient use of network bandwidth, or to reduce latency, among other examples). For example, the AI/ML model(s) may be trained to identify patterns or relationships in data corresponding to the wireless communication network 100, a device, or an air interface, among other examples. The AI/ML model(s) may support operational decisions relating to one or more aspects associated with wireless communications devices, networks, or services.

Accordingly, in some examples, the AI/ML model(s) may enable AI-as-a-Service (for example, an end-to-end AI/ML service via a user plane) for use cases, such as a self-organizing network (SON), minimization of drive test (MDT), quality of experience (QoE), positioning, sensing, predictive mobility, or traffic prediction, among other examples. In some examples, AI-as-a-Service use cases may include measurement collection reporting by a UE 120, device selection criteria (for example, according to a geographical area where measurements are to be collected or UE capabilities to be used to collected measurements), or reporting configurations (for example, reporting parameters such as location, time, or sensor information, among other examples). Additionally, or alternatively, the AI/ML model(s) may enable AI/ML procedures (for example, RAN-triggered service establishment, configuration, inferencing using UE-side or network-side models, performance monitoring or management, or capability signaling, among other examples). Additionally, or alternatively, the AI/ML model(s) may enable RAN-based AI/ML services via one or more application program interfaces (APIs) or management interfaces for use cases, such as beam management, radio resource monitoring (RRM) relaxation, mobility prediction, load prediction, network energy savings, or coverage and capacity improvements, among other examples.

As shown in FIG. 1, a first wireless communication device (WCD) 170 may communicate with a second WCD 175. The first WCD 170 may be a network node 110, a UE 120, or another type of WCD. The second WCD 175 may be a network node 110, a UE 120, or another type of WCD. The first WCD 170 may include a processing system 180. The second WCD 175 may include a processing system 185. The processing system 180 and the processing system 185 may be similar to the processing system 140 or the processing system 145. The WCD 170 may perform an encoding operation to generate encoded information (such as by selectively introducing redundancy into the information, typically using an ECC, such as an LDPC code). For example, the WCD 170 may provide or transmit, and the WCD 175 may obtain or receive, the encoded information. The WCD 175 may decode (or perform a decoding operation) on the encoded information to obtain the information, such as by using the ECC, such as the LDPC code.

In some aspects, the WCD 170 may include a communication manager 150. As described in more detail elsewhere herein, the communication manager 150 may obtain an encoded communication; and decode, using an LDPC code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge. Additionally, or alternatively, the communication manager 150 may obtain an encoded communication; and decode, using an LDPC code, the encoded communication to obtain a communication, the LDPC code being associated with a base graph that is in accordance with a stability metric condition. Additionally, or alternatively, the communication manager 150 may perform one or more other operations described herein.

In some aspects, the WCD 175 may include a communication manager 155. As described in more detail elsewhere herein, the communication manager 155 may encode, using an LDPC code, a communication to obtain an encoded communication, the LDPC code being associated with a base graph that includes a single punctured node and one or more check nodes, and the base graph being in accordance with a check degree condition that indicates that at least one check node, of the one or more check nodes, is connected to the single punctured node via a single edge; and provide the encoded communication. Additionally, or alternatively, the communication manager 155 may encode, using an LDPC code, a communication to obtain an encoded communication, the LDPC code being associated with a base graph that is in accordance with a stability metric condition; and provide the encoded communication Additionally, or alternatively, the communication manager 155 may perform one or more other operations described herein.

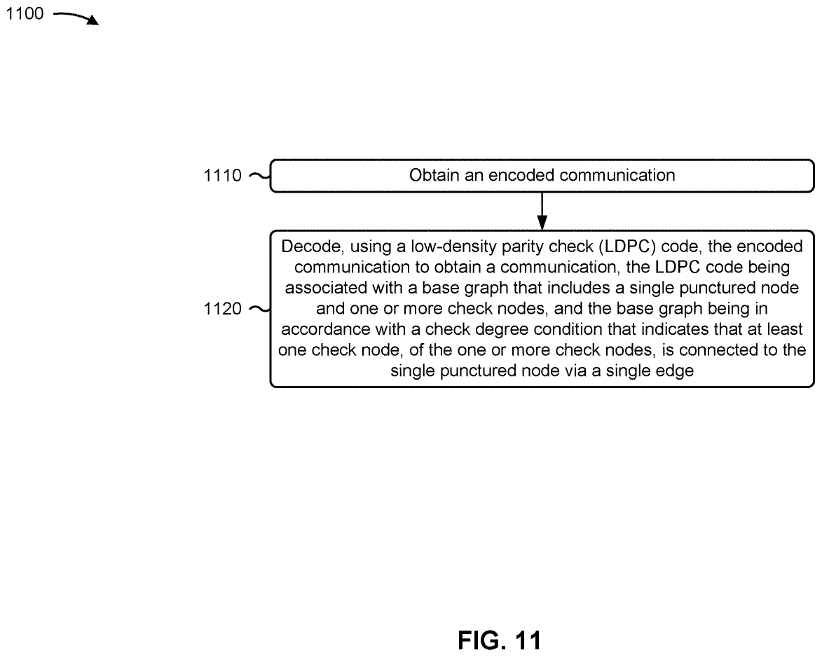

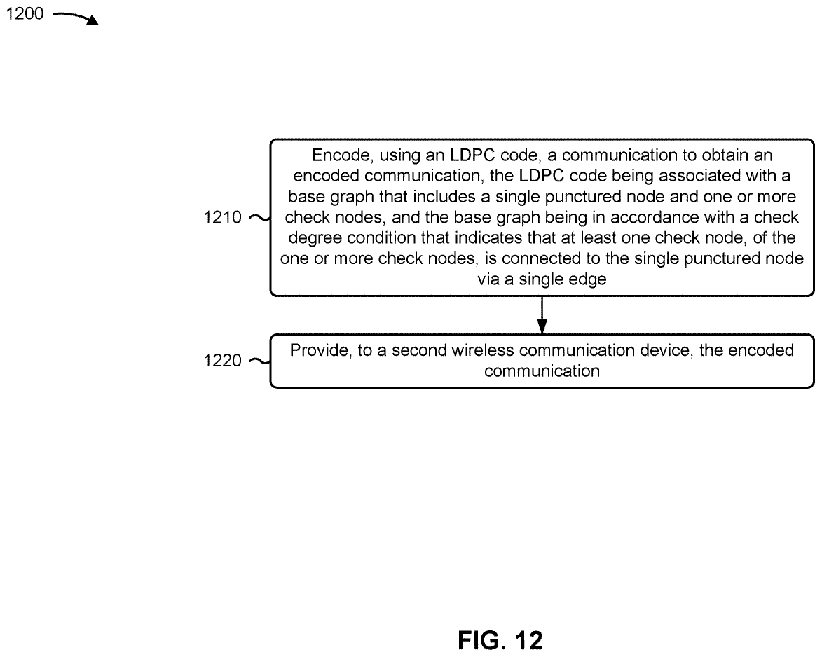

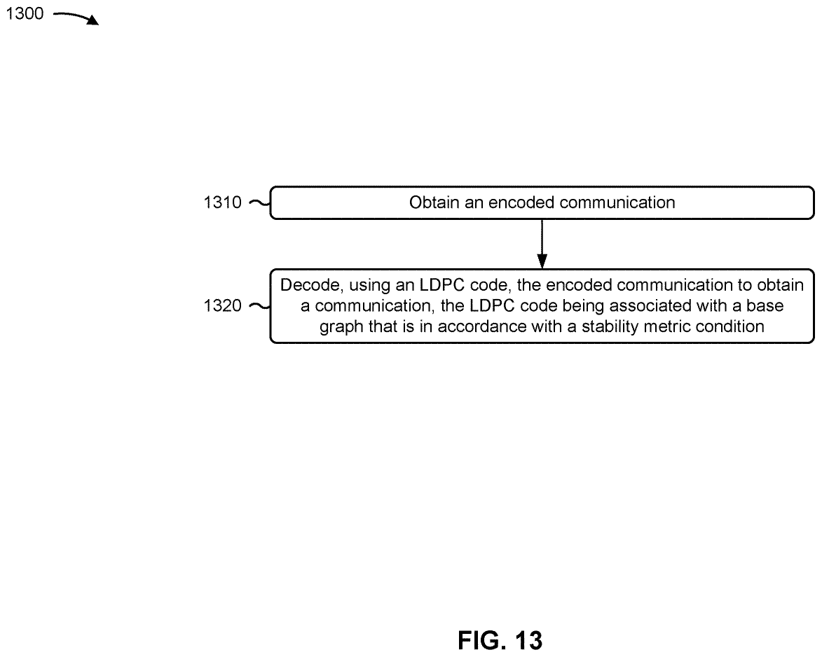

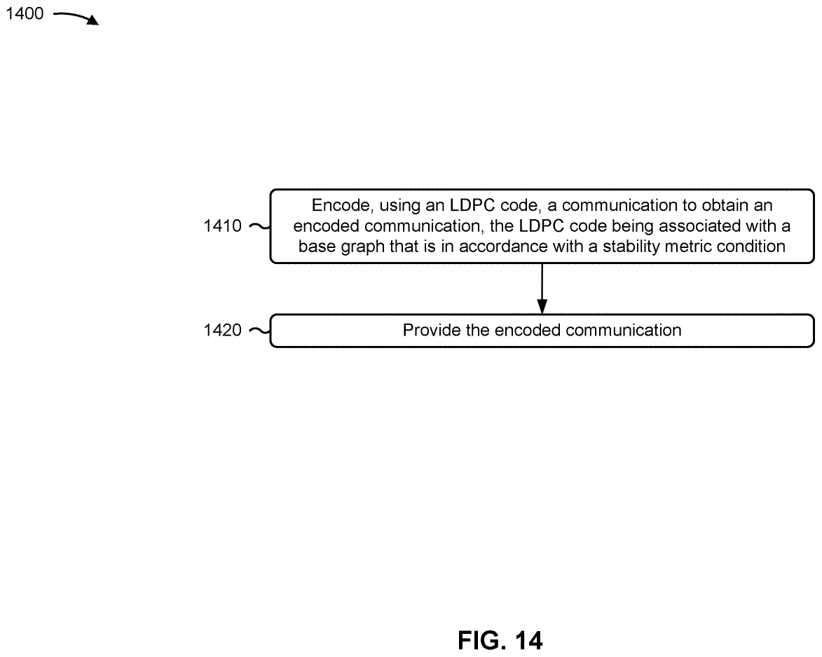

The network node 110, the processing system 145 of the network node 110, the UE 120, the processing system 140 of the UE 120, the processing system 180 of the WCD 170, the processing system 185 of the WCD 175, or any other component(s) of FIG. 1 may implement one or more techniques or perform one or more operations associated with conditions for LDPC codes, as described in more detail elsewhere herein. For example, the processing system 145 of the network node 110, the processing system 140 of the UE 120, the processing system 180 of the WCD 170, or the processing system 185 of the WCD 175 may perform or direct operations of, for example, process 1100 of FIG. 11, process 1200 of FIG. 12, process 1300 of FIG. 13, process 1400 of FIG. 14, or other processes as described herein (alone or in conjunction with one or more other processors). In some aspects, the WCD described herein is the network node 110, is included in the network node 110, or includes one or more components of the network node 110 shown in FIG. 1. In some other aspects, the WCD described herein is the UE 120, is included in the UE 120, or includes one or more components of the UE 120 shown in FIG. 1. Memory of the network node 110 may store data and program code (or instructions) for the network node 110. In some examples, the memory of the network node 110 may store data relating to a UE 120, such as RRC state information or a UE context. Memory of a UE 120 may store data and program code (or instructions) for the UE 120, such as context information. In some examples, the memory of the UE 120 or the memory of the network node 110 may include a non-transitory computer-readable medium storing a set of instructions for wireless communication. For example, the set of instructions, when executed by one or more processors (for example, of the processing system 145, the processing system 140, the processing system 180, or the processing system 185) of the network node 110, or the UE 120, may cause the one or more processors to perform process 1100 of FIG. 11, process 1200 of FIG. 12, process 1300 of FIG. 13, process 1400 of FIG. 14, or other processes as described herein. In some examples, executing instructions may include running the instructions, converting the instructions, compiling the instructions, or interpreting the instructions, among other examples.

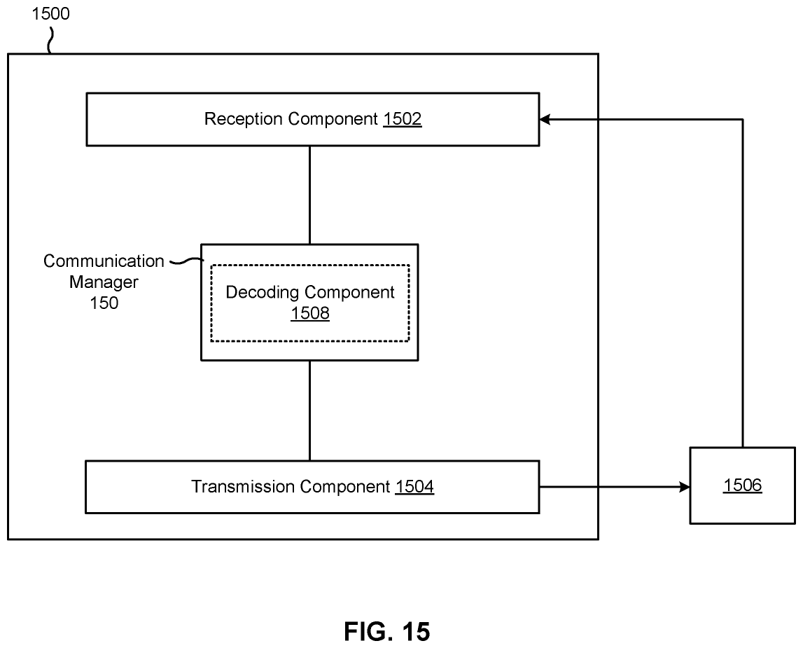

In some aspects, a WCD (such as the WCD 170) includes means for obtaining an encoded communication; or means for decoding, using an LDPC code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge. Additionally, or alternatively, the WCD includes means for obtaining an encoded communication; or means for decoding, using an LDPC code, the encoded communication to obtain a communication, the LDPC code being associated with a base graph that is in accordance with a stability metric condition. In some aspects, the means for the WCD to perform operations described herein may include, for example, one or more of communication manager 150, processing system 180, a radio, one or more RF chains, one or more transceivers, one or more antennas, one or more modems, a reception component (for example, reception component 1502 depicted and described in connection with FIG. 15), or a transmission component (for example, transmission component 1504 depicted and described in connection with FIG. 15), among other examples

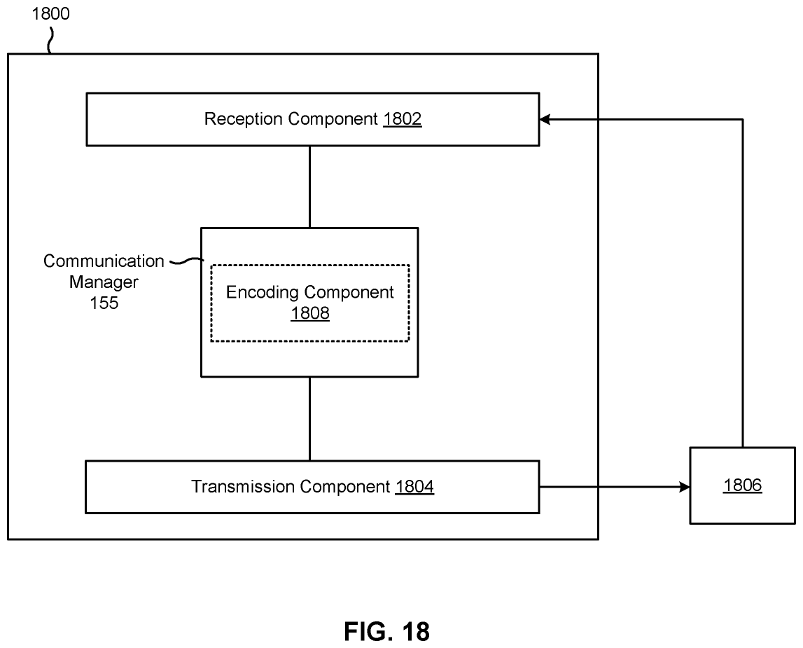

In some aspects, a WCD (such as the WCD 175) includes means for encoding, using an LDPC code, a communication to obtain an encoded communication, the LDPC code being associated with a base graph that includes a single punctured node and one or more check nodes, and the base graph being in accordance with a check degree condition that indicates that at least one check node, of the one or more check nodes, is connected to the single punctured node via a single edge; or means for providing the encoded communication. Additionally, or alternatively, the WCD includes means for encoding, using an LDPC code, a communication to obtain an encoded communication, the LDPC code being associated with a base graph that is in accordance with a stability metric condition; or means for providing the encoded communication. In some aspects, the means for the WCD 175 to perform operations described herein may include, for example, one or more of communication manager 155, processing system 185, a radio, one or more RF chains, one or more transceivers, one or more antennas, one or more modems, a reception component (for example, reception component 1802 depicted and described in connection with FIG. 18), or a transmission component (for example, transmission component 1804 depicted and described in connection with FIG. 18), among other examples.

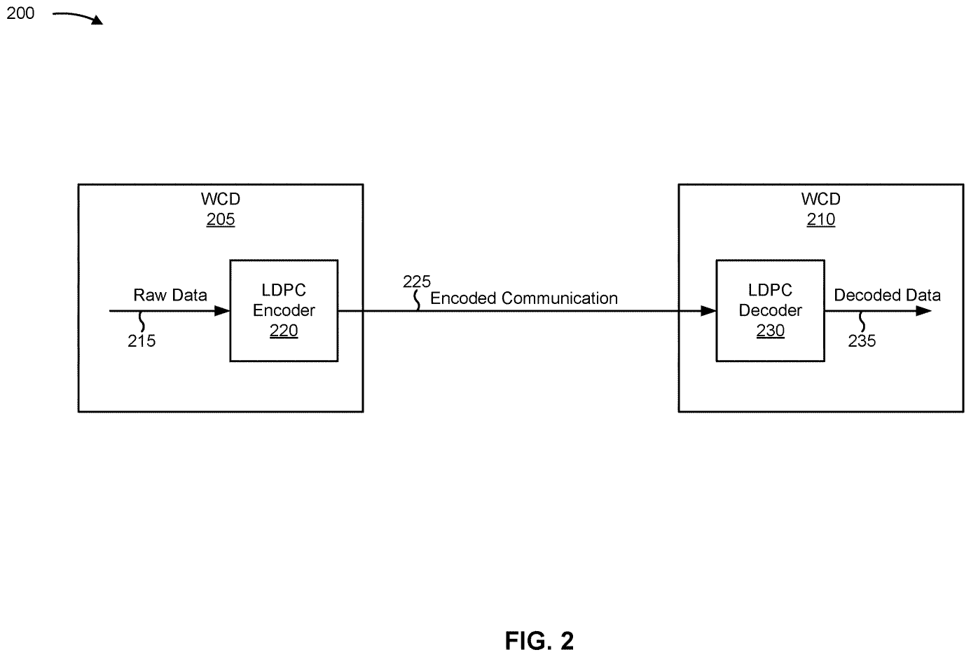

FIG. 2 is a diagram illustrating an example 200 of communication using LDPC codes. As shown in FIG. 2, example 200 includes communication between a first WCD, shown in FIG. 2 and referred to herein as WCD 205, and a second WCD, shown in FIG. 2 and referred to herein as WCD 210. The WCD 205 may be a network node 110, a UE 120, or the WCD 170. The WCD 210 may be a network node 110, a UE 120, or the WCD 175. As shown in FIG. 2, the WCD 205 includes an LDPC encoder 220 and the WCD 210 includes an LDPC decoder 230, which the WCD 205 and the WCD 210 may use to implement an LDPC channel coding scheme in which LDPC codes are used for one or more data channel transmissions. For example, in some aspects, the WCD 205 may correspond to a network node 110 and the WCD 210 may correspond to a UE 120, and the LDPC channel coding scheme may be used for one or more PDSCH transmissions from the network node 110 to the UE 120. Additionally, or alternatively, the WCD 205 may correspond to a UE 120 and the WCD 210 may correspond to a network node 110, and the LDPC channel coding scheme may be used for one or more PUSCH transmissions from the UE 120 to the network node 110. Additionally, or alternatively, the WCD 205 may correspond to a first UE 120 and the WCD 210 may correspond to a second UE 120, and the LDPC channel coding scheme may be used for one or more physical sidelink shared channel (PSSCH) transmissions from the first UE 120 to the second UE 120. In some aspects, the WCD 205 and the WCD 210 may communicate in a wireless network, such as the wireless communication network 200.

In some aspects, a communication from the WCD 205 to the WCD 210 may be encoded based at least in part on an error correcting code (sometimes referred to as an error correcting scheme), such that the WCD 210 can determine whether the communication was properly transmitted (e.g., to verify that the communication was not corrupted by noise or the like) or so that the WCD 210 can correct any transmission errors using redundant bits provided by the error correcting code. One example of an error correcting code is an LDPC code. A communication may be encoded according to an LDPC channel coding scheme to provide for error detection at the WCD 210. Encoding for an LDPC code may be performed based at least in part on a base graph (e.g., a sparse bipartite graph) that may identify a codeword to be generated from an input data set or information to append to an input data set to form the LDPC code.

More particularly, as shown in FIG. 2, the WCD 205 may be in wireless communication with the WCD 210. When the WCD 205 transmits data to the WCD 210, the WCD 205 may first encode the data using an error correcting code, such as an LDPC code. For example, as shown in FIG. 2, the WCD 205 may process raw data 215 (e.g., information bits) to be transmitted to the WCD 210 by feeding the raw data 215 through the LDPC encoder 220, among other signal processing components. The WCD 205 may perform other signal processing operations (e.g., interleaving or the like), which are not shown in FIG. 2. The LDPC encoder 220 may add error correction bits (e.g., parity bits) to the raw data 215 based at least in part on a selected base graph or based at least in part on a target code rate, forming an encoded data stream 225. In some examples, the target code rate may be expressed as R=k/n, where R is the target code rate, k is a number of information bits in the raw data 215 input to the LDPC encoder 220, and n is a total number of bits in the encoded data stream transmitted to the WCD 210 (e.g., the target code rate is the proportion of the encoded data stream 225 that is useful, or non-redundant). For example, LDPC codes associated with a lower code rate provide more error protection, but may incur more overhead, relative to LDPC codes with a higher code rate.

As further shown in FIG. 2, the WCD 205 may transmit the encoded data stream 225 to the WCD 210 over a wireless link (e.g., a wireless access link for uplink or downlink communication, or a wireless sidelink for sidelink communication), where the encoded data stream 225 is fed through the LDPC decoder 230 (and, in some examples, other signal processing components such as a de-interleaver, among other examples) in order to recover the information bits from decoded data 235 output from the LDPC decoder 230. For example, the LDPC decoder 230 may use an iterative belief propagation decoding scheme (also known as a message passing decoding scheme) to decode the encoded data stream 225.

As indicated above, FIG. 2 is provided as an example. Other examples may differ from what is described with regard to FIG. 2.

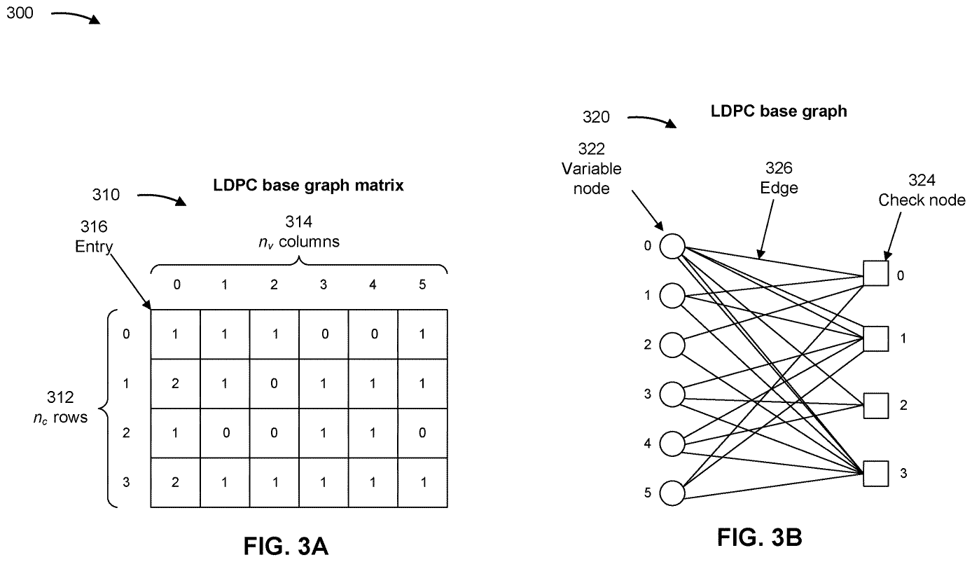

FIGS. 3A and 3B are diagrams illustrating an example 300 of an LDPC base graph matrix 310 and an LDPC base graph 320. As described herein, the LDPC base graph matrix 310 and the LDPC base graph 320 may be used to encode an LDPC code, which is a linear block code that can provide error correction capabilities that may be close to channel capacity. For example, the LDPC base graph matrix 310 and the LDPC base graph 320 may be used by the LDPC encoder 220 of the WCD 205 to encode the raw data 215 (e.g., to generate the encoded data stream 225). In some examples, an LDPC code may be represented according to a base graph (for example, a sparse bipartite graph) that may identify a codeword to be generated from an input data set or information to append to an input data set to form the LDPC code. For example, a bipartite graph may include variable nodes representing information bits (also known as message bits or systematic bits) and check nodes representing parity-check equations. The edges between the variable nodes and the check nodes may define how the information bits are related through the parity-check equations, which may be solved using the input data set to determine the values of the parity bits. For example, the original information bits may be combined with the parity bits to form an LDPC code containing the input data (information bits) and the error-correcting (parity) bits.

As shown in FIG. 3A, the LDPC base matrix 310 has a size n_{c}×nᵥ including a total number of n_{c} rows 312 and a total number of nᵥ columns 314. Additionally, both n_{c} and nᵥ are positive integers, and the total number of rows n_{c} may be smaller than the total number of columns nᵥ. Each entry 316 of the LDPC base matrix 310 is a non-negative integer in a set of integers ranging from 0 to a bounded integer that is independent of the size of the LDPC base matrix 310. For example, the set of integers may be {0,1}, {0,1,2}, or {0,1,2, . . . , dₘₐₓ} for some dₘₐₓ integer. Additionally, each row 312 of the LDPC base matrix 310 may be indexed by a respective integer from 0 to n_{c}−1. Each column 314 of the LDPC base matrix 310 may be indexed by a respective integer from 0 to nᵥ−1.

As further shown in FIG. 3B, the LDPC base graph matrix 310 is associated with an LDPC base graph 320 that represents the LDPC base matrix 310. In some examples, the LDPC base graph 320 may be a bipartite graph including a set of variable nodes 322, a set of check nodes 324, and a set of edges 326 connecting the set of variable nodes 322 and the set of check nodes 324. For example, each variable node 322 may be labelled by a respective integer from 0 to nᵥ−1, such that each variable node 322 corresponds to a column 314 of the LDPC base matrix 310. Furthermore, each check node 324 may be labelled by a respective integer from 0 to n_{c}−1, such that each check node 324 corresponds to a row 312 of the LDPC base matrix 310. Additionally, an edge 326 exists between a variable node i and a check node a if a value of the entry at (column a, row i) of the LDPC base matrix 310 is non-zero, and the number of edges between the variable node i and the check node a is equal to the value of the entry at (column a, row i) in the LDPC base matrix 310. For example, the entry at (column 0, row 0) of the LDPC base matrix 310 has a value of 1, which is represented in the edge 326 between variable node 0 and check node 0. In some examples, multiple edges 326 exist between a variable node i and a check node a if a value of the entry at (column a, row i) of the LDPC base matrix 310 is greater than one. Furthermore, a variable node 322 is a state node if a corresponding column 314 of the LDPC base matrix 310 is a state column. In addition, a state variable or state column may refer to a variable node of an LDPC code associated with a non-transmitted (e.g., punctured) set of information bits.

As indicated above, FIGS. 3A and 3B are provided as examples. Other examples may differ from what is described with regard to FIGS. 3A and 3B.

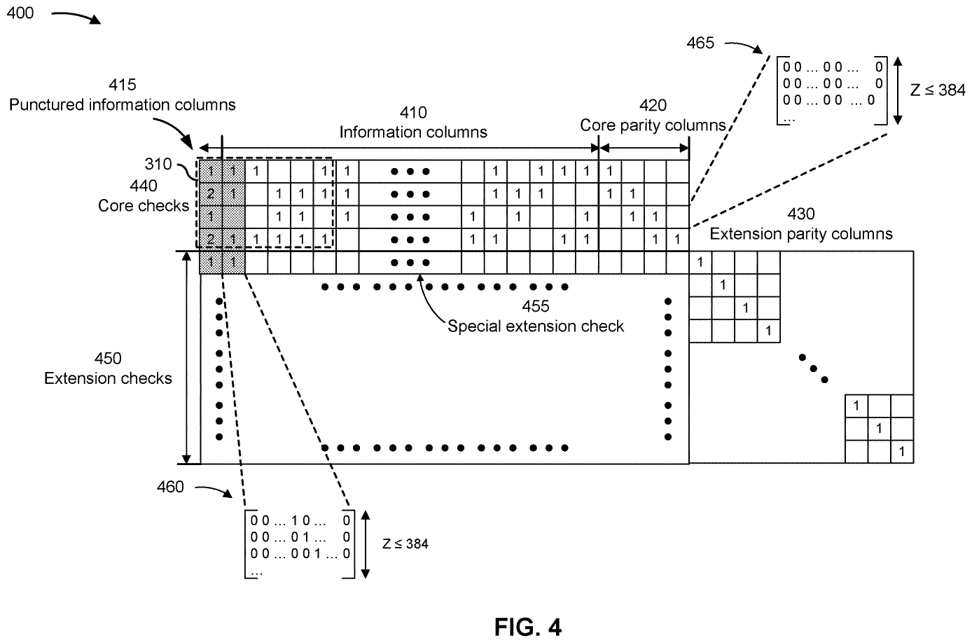

FIG. 4 is a diagram illustrating an example of a PCM 400 associated with an LDPC code. As described herein, the PCM shown in FIG. 4 may be used for a QC-LDPC code, where the PCM 400 has a compact representation that may enable efficient LDPC encoding and high parallelism in a corresponding LDPC decoder architecture. In some examples, the PCM shown in FIG. 4 may be used by the WCD 205 to encode the raw data 215 via the LDPC encoder 220. Similarly, the PCM shown in FIG. 4 may be used by the WCD 210 to decode the encoded data stream 225 via the LDPC decoder 230. As shown in FIG. 4, the LDPC base graph matrix 310 may be a portion of the PCM 400.

For example, the PCM 400 is a set of codewords that satisfy one or more parity check conditions, which may be defined according to a base graph and lifting values (also known as a protograph LDPC code). In particular, as described herein, the base graph (or protograph) is a small graph that captures macroscopic properties associated with the QC-LDPC code, such as a decoding threshold. After the base graph has been constructed, a lifting procedure is applied in which the base graph is copied multiple times and connections between different copies of the base graph are permuted to construct one larger graph. Otherwise, without permuting the different copies of the base graph into one larger graph, there would be K small graphs that are not connected to each other, which may result in no coding gain. The copying and permutation is a cyclic permutation along edges of the base graph, and is generally known as cyclic shift lifting. Accordingly, the LDPC code resulting from the encoding procedure of constructing the base graph and applying the lifting procedure is known as a quasi-cyclic LDPC code.

In some examples, the base graph associated with an LDPC code (such as the LDPC base graph 320) may be described or represented as a matrix (or base graph matrix), such as the PCM 400 shown in FIG. 4. For example, as shown in FIG. 4, the PCM includes a set of information columns 410, a set of core parity columns 420, and a set of extension parity columns 430, which represent variable nodes associated with the PCM. In addition, the PCM includes a set of core check rows 440 and a set of extension check rows 450, which represent check nodes associated with the PCM. The extension check rows 450 include a special extension check 455, and the information columns include one or more punctured information columns 415. For each entry in the PCM, the value is a non-negative integer representing the number of connections between the variable node and the check node corresponding to the entry (e.g., a 0 means that there is no connection between the corresponding variable node and check node, a 1 means that there is 1 edge connecting the corresponding variable node and check node, a 2 means that there are 2 edges connecting the corresponding variable node and check node, and so on). As described herein, each variable node has a degree that denotes the number of check nodes that the variable node is connected to in the base graph (e.g., the number of rows with a positive value), where a degree-n variable node is connected to n check nodes. The extension check rows 450 include a special extension check 455, and the information columns include one or more punctured information columns 415.

As further shown in FIG. 4, and by reference number 460, each entry that has a positive value (e.g., one) may be replaced by a permuted identity matrix that indicates the number of cyclic permutations applied to each edge in the base graph. The lifting values may be integers in a range between 0 and Z, where Z is a lift value (e.g., the number of copies that are applied to the base graph). Accordingly, after constructing the base graph and applying the lifting procedure, the resulting QC-LDPC code has a block length equal to the size of the base graph multiplied by the lifting factor. As shown by reference number 465, each entry that has a value of zero may be replaced by a Z×Z matrix having all entries with a value of zero.

As indicated above, FIG. 4 is provided as an example. Other examples may differ from what is described with regard to FIG. 4.

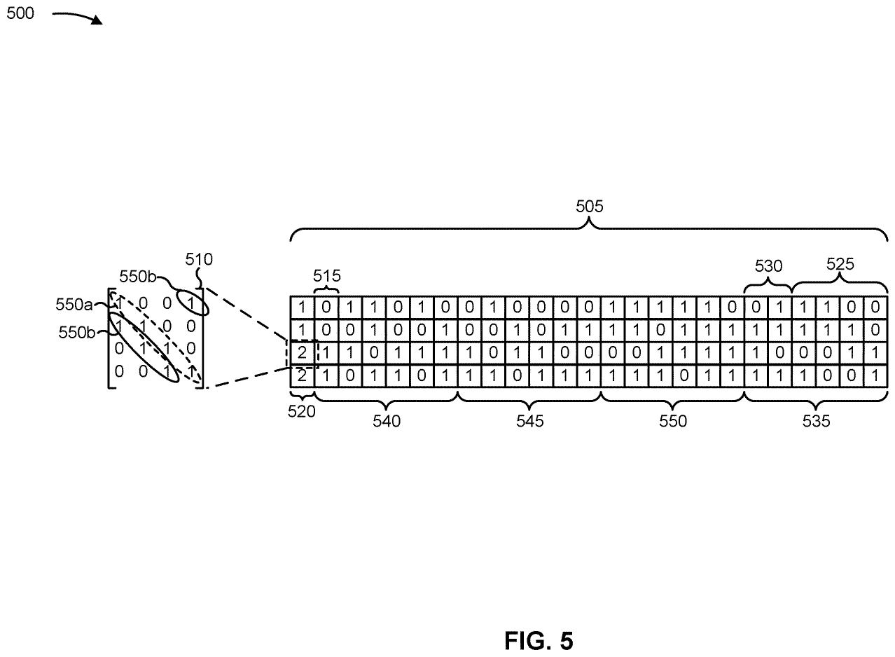

FIG. 5 is a diagram illustrating an example 500 of a base graph 505 that supports fast converging LDPC techniques. For example, transmissions between two WCDs, such as the WCD 170 and the WCD 175, may be encoded according to an LDPC code. In such examples, a transmitting device may transmit a signal including one or more coded bits to a receiving device based on encoding the signal. The receiving device may decode the signal based on receiving the signal and generating an LDPC code associated with the signal.

The transmitting device may generate the LDPC code based on a base graph 505. The transmitting device or the receiving device, or both, may perform lifting on the base graph 505 according to a lifting matrix 510, which may be an example of a dual-diagonal lifting matrix. The base graph 505 may include one or more variable nodes 515. The base graph 505 may include a punctured variable node 520, which may be in a first node position. In some examples, the punctured variable node 520 may be an example of a punctured variable node having double-edged or multi-edged elements. The base graph 505 may include a set of parity nodes 525 and a set of unshaped bits 530 (e.g., unshaped systematic bits). The set of unshaped bits 530 may be at the beginning of the set of information nodes of the base graph 505 or at the end of the set of information nodes of the base graph 505. In some examples, the portion of the base graph 505 shown in FIG. 5 may be an example of a core of the base graph 505.

In some examples, each of the one or more variable nodes 515 may be associated with a degree. In such examples, a numerical value associated with each degree may indicate that each of the one or more variable nodes 515 is associated with a quantity of check nodes similar to (e.g., equal to) the numerical value associated with each degree. For example, one or more variable nodes 515 of the base graph 505 may be associated with two check nodes (e.g., second degree nodes), and one or more variable nodes 515 of the base graph 505 may be associated with three check nodes (e.g., third degree nodes). In an example, the punctured variable node 520 may have a degree of six based on having two double-edged elements and two single-edged elements.

The base graph 505 may include a single punctured node (e.g., the punctured variable node 520), which may provide faster convergence compared to base graphs with two punctured nodes. The single punctured node may have double-edge or multi-edge elements in the base graph, which may improve asymptotic performance. For example, the total degree of punctured nodes may be increased by supporting multiple edges to a same check node. The base graph 505 may converge faster than other base graphs (e.g., base graphs with more than a single punctured node). In some examples, the base graph 505 may have a larger core size than some other base graphs. The rate of the core may be greater than or equal to the rate of the core of some other systems. For example, the rate of the core of the base graph 505 may be greater than or equal to 0.88 (e.g., for high throughput scenarios).

The punctured nodes may provide threshold improvement. For example, the punctured node may increase the check node degree of the transmitted graph. The double edge structure may provide faster convergence and improved asymptotic performance. In some examples, the base graph 505 may support using an encoding chain of degree two and a HARQ extension of degree one. In some examples, the set of parity nodes 525 may have an accumulative chain structure which may be similar to some other base graphs (e.g., BG1).

In some examples, the base graph 505 may be implemented by a device by converting a double-edge graph into a single-edge format. For example, the device may use or introduce a virtual punctured node corresponding to a special check or special layer. A decoding device may use a decoding schedule where the decoding device revisits the special layer after every layer involving the double edge. For example, the virtual punctured layer may store a separate copy of a log likelihood ratio. A parity check may equate the punctured node and the virtual node. For example, a device may effectively add a virtual row (e.g., a virtual check node) and a virtual column (e.g., a virtual variable node) to the base graph, such that a second edge between the punctured variable node is effectively moved to the virtual variable node.

The transmitting device or the receiving device, or both, may perform lifting on both edges of an entry of the punctured variable node 520 with two edges. For example, the entry of the punctured variable node 520 with two edges may be replaced by a summation of two circularly shifted identity matrices. A first identity matrix may have a first circular shift value 550-a, and a second identity matrix may have a second circular shift value 550-b. In the example shown by FIG. 5, the first circular shift value 550-a may be zero (e.g., the identity matrix is not circularly shifted), and the second circular shift value 550-b may be three. The lifting matrix 510 for the double-edge entry of the punctured variable node 520 may correspond to a summation of the two identity matrices with the respective circular shift values.

For the lifting procedure, each value of 1 in the base graph 505 may be replaced by a circularly shifted identity matrix. The circular shift values may be configured at the transmitting device or the receiving device, or preconfigured for a wireless communications system including the transmitting device and receiving device. For each lift value (e.g., Z value), the lift values (e.g., or circular shift values) may be stored by a lift value matrix. For example, a 0 in the base graph 505 (e.g., no edge) may correspond to a −1 in the lift value matrix. A non-zero value (e.g., 1 or 2) in the base graph 505 may correspond to a lifting value in the lift value matrix. To specify lift values for double edges, the lift value matrix may indicate two lifting values for double edges in the base graph 505. In a first example, the lift value matrix may indicate two values, A and B. For example, the entry in the lift value matrix that corresponds to a double edge may store both A and B, or two separate lift values or circular shift values for the double edge. In another example, the entry in the lift value matrix that corresponds to the double edge may store a single value that is indicative of both lift values. For example, the entry may store a value that is based on the first lift value, the second lift value, and a lift size. For example, the entry in the lift value matrix may correspond to A+10×Z×B. In an example, for a lifting size value of Z=384, a first lifting value A of 181, and a second lifting value B of 186, the entry in the lifting value matrix will be 714421.

In the example shown by FIG. 5, the Z value or lifting size value for the base graph may be four. For example, the dimensions of the lifting matrix 510 may be Z×Z, or four columns with four rows. The Z value for FIG. 5 is an example, and other Z values may be used for a lifting size. In some examples, the lift size may be less than or equal to 384. In some implementations, the lift size may be configured to be larger than a threshold, which may prevent short cycles in an LDPC code. In some examples, Z value may be restricted or configured to be larger than a threshold size.

In some examples, the core of the base graph 505 may have a higher occurrence or density of double edges than an extension portion of the base graph 505. An example of the extension portion may be the extension checks 450 depicted and described in connection with FIG. 4. In some examples, the extension portion of the base graph 505 may refer to lower check nodes, or check nodes five and beyond. The extension may have more single edges for faster convergence. For example, a majority of layers of the punctured node in the extension portion may have single edges.

In some examples, the transmitting device may map the elements of the base graph 505 (e.g., one or more parity bits and one or more unshaped bits of the coded bit) to different bits of a modulation constellation. For example, a first set of variable nodes may correspond to a first most significant bit (MSB) 540, a second set of variable nodes may correspond to a second MSB 545, a third set of variable nodes may correspond to a third MSB 550, and a fourth set of variable nodes may correspond to the least significant bit (LSB) 535.

A receiving device may receive a signal including information bits and parity bits according to the LDPC code. In some examples, the receiving device may generate the LDPC code according to a lifted graph. The lifted graph may include multiple connected copies of the base graph that are connected via edge permutation based on a lifting procedure. The receiving device may attempt to decode the information bits based on the parity bits, information nodes, and parity nodes. In some examples, the receiving device may perform layered decoding to decode the information bits. For example, the receiving device may decode single edge layers first, then decode double edge layers. For example, the receiving device may decode the first and second layers (e.g., rows) of the base graph 505, then the receiving device may decode the third and fourth layers of the base graph 505. In some examples, the receiving device may start decoding from a lowest degree layer and finish decoding with a highest degree layer. In some examples, the receiving device may not connect a variable node to the parity checks that are decoded consecutively in the layered decoding. For example, a message update may not be ready based on a pipeline of the bits or the implementation. In some examples, asymmetric degree distribution for parity check nodes may assist layered decoding. In some examples, the base graph 505 may support degree one extension structure to assist decoding operations at the receiving device.

As indicated above, FIG. 5 is provided as an example. Other examples may differ from what is described with regard to FIG. 5.

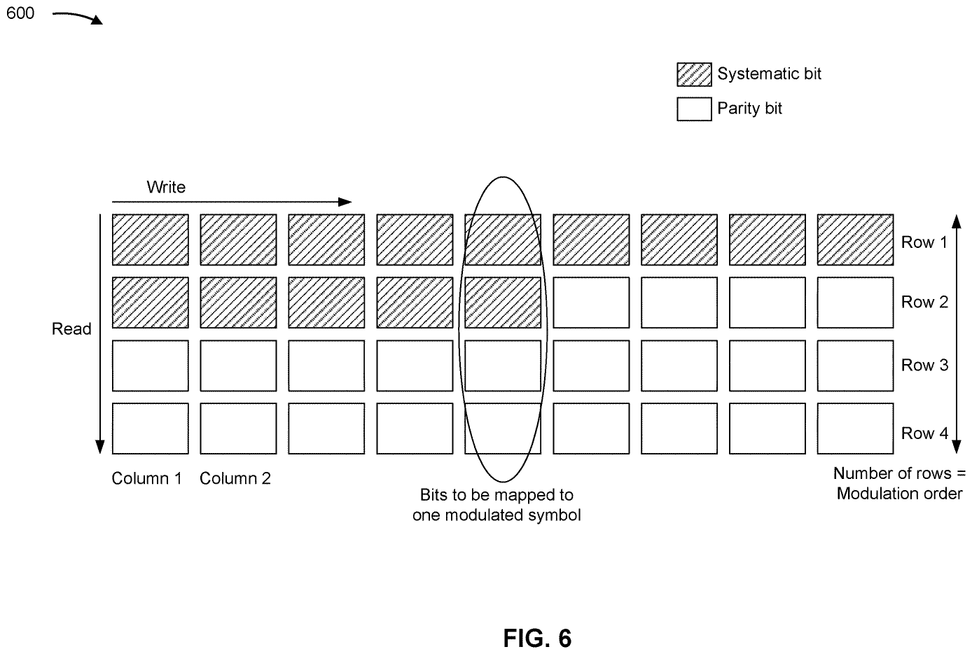

FIG. 6 is a diagram illustrating an example 600 of mapping coded bits. In some examples, interleaving may be performed after (or as the last operation of) rate matching to map bits to symbols for modulation. Interleaving may improve reliability of a transmitted communication by, for example, improving robustness of forward error correction at a receiver, such as the WCD 210. For example, interleaving may result in bits, which are consecutive prior to interleaving, being spaced out (e.g., in MIMO layers, frequency, or time) such that some of those bits are no longer consecutive. This may mitigate the effects of burst errors, thereby reducing local gaps in communications, such as gaps in voice, video, data, or other communications.

A communication transmitted over the air may include systematic bits (e.g., also referred to as information bits or message bits) and parity bits (e.g., also referred to as check bits), which together form coded bits (e.g., a codeword) of the communication. The systematic bits may carry the information to be conveyed, and the parity bits may be used for error detection or error correction (e.g., using a checksum, or a cyclic redundancy check). In some aspects, the parity bits are a function of or determined based at least in part on the systematic bits.

SBPM is a technique to map systematic bits of a communication to the most significant bits of each modulated symbol of the communication. This increases reliability due to an increased likelihood of correct demodulation of the systematic bits because the most significant bits (e.g., the most significant bit, or one or more most significant bits) of the modulated symbol have increased protection against errors as compared to the least significant bits (e.g., the least significant bit, or one or more least significant bits) of the modulated symbol when using conventional modulation constellations, such as PSK or QAM. For example, even if a receiver incorrectly demodulates a modulated symbol, that incorrect demodulation is likely to correspond to a constellation point, in a constellation diagram for the conventional modulation scheme, that is near the correct constellation point and that has one or more most significant bits in common with the correct constellation point. SBPM may be referred to as a bit-to-modulation mapping technique. For example, SBPM may be a technique for mapping coded bits (e.g., bits from the encoded data stream 225) to modulation constellation symbols for over-the-air transmission.

An example of SBPM interleaving (e.g., using block interleaving) is shown in FIG. 6. In some examples, SBPM interleaving may be referred to as a depth-m block interleaving. In example 600, each block represents a bit, which may be a systematic bit or a parity bit, as shown. A column of blocks represents a number of bits that are mapped to a single symbol (e.g., a single modulated symbol). The number of bits (e.g., the number of rows in a column) is equal to the modulation order. Thus, interleaving may be a function of modulation order. In example 600, each modulated symbol represents 4 bits, which has a modulation order of 4 (e.g., 4 bits per symbol). The number of columns may depend on the size of the communication to be transmitted. For example, the number of columns may be equal to the total number of coded bits (e.g., systematic bits plus parity bits) to be transmitted, divided by the modulation order. In example 600, there are 36 coded bits to be transmitted with a modulation order of 4, leading to 9 columns of blocks.

In some aspects, block interleaving (e.g., SBPM interleaving) may be performed using a technique called write by row, read by column. Using this technique, bits may be obtained from a circular buffer as part of a rate matching process, with a starting bit determined based at least in part on a redundancy version, of the communication, to be transmitted. As the bits are obtained, those bits may be written to blocks across a first row (shown as row 1), where each bit is placed in a different column corresponding to a different symbol. After the first row is filled, bits may be written to blocks across a second row (shown as row 2), and so on. The starting bit and a set of subsequent bits of the circular buffer may be systematic bits, and may be followed by parity bits. As a result, the first one or more rows (shown toward the top of FIG. 6) may include systematic bits, and the last one or more rows (shown toward the bottom of FIG. 6) may include parity bits.

Because the first row(s) correspond to more significant bits (e.g., MSBs) of the modulated symbol and the last row(s) correspond to less significant bits (e.g., LSBs) of the modulated symbol, this technique may map systematic bits (e.g., some, most, or all of the systematic bits, depending on a starting bit in the circular buffer) to the most significant bit(s) of the modulated symbol, thereby increasing reliability, as described above. In example 600, the first row corresponds to the MSB of the modulated symbol, and is filled entirely with systematic bits, and the last row corresponds to the LSB of the modulated symbol, and is filled entirely with parity bits.

After all of the coded bits are written to the blocks, referred to as interleaving, those interleaved bits are read from the blocks down a first column (e.g., shown as column 1) as input to a modulation process to modulate those coded bits in a modulated symbol. After modulation, the coded bits in the first column will be represented as a first modulated symbol, the coded bits in a second column (e.g., shown as column 2) will be represented as a second modulated symbol, and so on. In some aspects, the interleaving or the modulation may be performed to first map the modulated symbols to a layer (e.g., a MIMO layer), then map the modulated symbols to a frequency, and then map the modulated symbols to time. In this way, protection from burst errors may be enhanced.

As an example, an SBPM scheme may enable a transmitter (e.g., the WCD 205 via the LDPC encoder 220) to map the systematic portion of coded bits (e.g., LDPC coded bits) to the MSB of a modulation constellation, and to map the non-systematic portion to the LSB of the modulation constellation. Without applying SBPM, each variable node in the base graph may experience, on average, the same channel conditions or reliabilities. As a result of applying SBPM, copies of the same variable node in a base graph may be associated with similar channel reliabilities, and different variable nodes in the base graph may experience different channel reliabilities. By improving a likelihood of copies of the same variable node in a base graph being associated with similar channel reliabilities (e.g., by mapping them consistently to the MSB or LSB, for example), the SBPM scheme may improve a decoding threshold for a channel coding scheme, such as the QC-LDPC coding scheme described herein, such as in connection with FIGS. 3-5.

As indicated above, FIG. 6 is provided as an example. Other examples may differ from what is described with regard to FIG. 6.

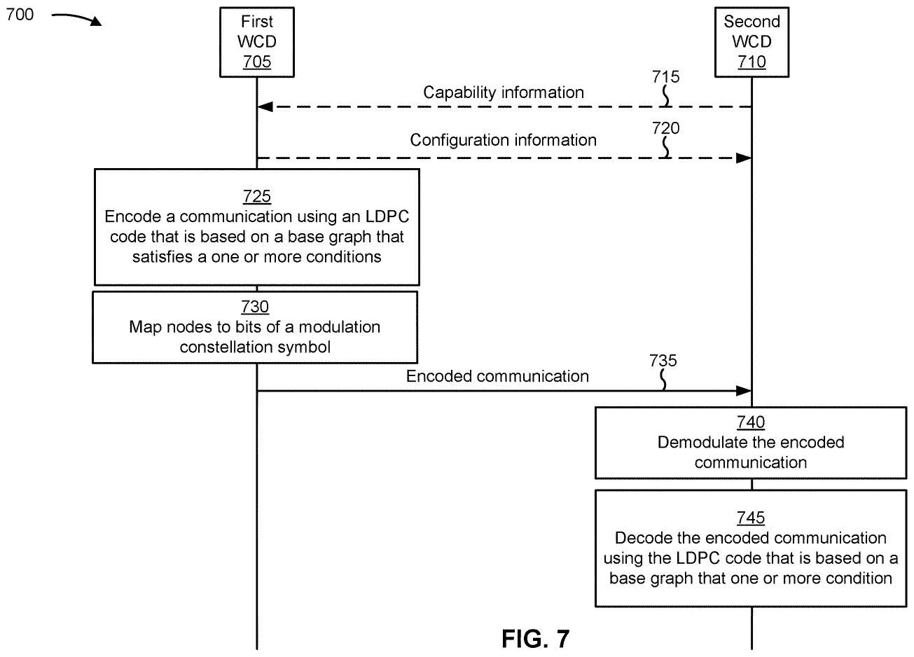

FIG. 7 is a diagram illustrating an example 700 associated with a rank condition for LDPC codes. As shown in FIG. 7, a first WCD 705 (e.g., a network node 110, a UE 120, or the WCD 170) may communicate with a second WCD 710 (e.g., a network node 110, a UE 120, or the WCD 175). In some aspects, the first WCD 705 and the second WCD 710 may be part of a wireless network (e.g., the wireless communication network 100). The first WCD 705 and the second WCD 710 may have established a wireless connection prior to operations shown in FIG. 7.

In some aspects, as shown by reference number 715, the first WCD 705 or the second WCD 710 (e.g., shown as the second WCD 710 in FIG. 7) may transmit capability information. The capability information may be included in a capability report. In an example where the second WCD 710 is a UE 120, the second WCD 710 may transmit the capability information via an uplink communication, a sidelink communication, a unicast communication, a broadcast communication, a UE assistance information (UAI) communication, a UCI communication, a sidelink control information (SCI) communication, a MAC-CE communication, an RRC communication, a PUCCH, a PUSCH, a physical sidelink control channel (PSCCH), or a PSSCH, among other examples. The capability information may indicate one or more parameters associated with respective capabilities of the second WCD 710. The one or more parameters may be indicated via respective information elements (IEs) included in a capability report. In some aspects, the first WCD 705 may transmit the capability information in addition to, or instead of, the second WCD 710.

The capability information may indicate whether the second WCD 710 supports a feature or one or more parameters related to the feature. For example, the capability information may indicate a capability or parameter for one or more base graphs or base graph matrices. As another example, the capability information may indicate a capability or parameter for using LDPC codes that are based on (or generated using) a base graph that satisfies one or more conditions, such as a check degree condition, a stability metric condition, or a degree-2 condition, among other examples. One or more operations described herein may be based on capability information. For example, the UE 120 may perform a communication in accordance with the capability information, or may receive configuration information that is in accordance with the capability information.

In some aspects, as shown by reference number 720, the first WCD 705 may transmit or provide, and the second WCD 710 may receive or obtain, configuration information. In other aspects, the second WCD 710 may transmit, and the first WCD 705 may receive, the configuration information. In some aspects, the first WCD 705 or the second WCD 710 may receive the configuration information via one or more of system information signaling (e.g., a master information block (MIB) or a system information block (SIB), among other examples), RRC signaling, MAC signaling (e.g., one or more MAC-CEs), or physical layer signaling (e.g., DCI), among other examples.

In some aspects, the configuration information may indicate one or more candidate configurations or communication parameters. In some aspects, the one or more candidate configurations or communication parameters may be selected, activated, or deactivated by a subsequent indication. For example, the subsequent indication may select a candidate configuration or communication parameter from the one or more candidate configurations or communication parameters. In some aspects, the subsequent indication may include a dynamic indication, such as one or more MAC-CEs or one or more DCI messages, among other examples.

In some aspects, the configuration information may include an indication of a selection of one or more configuration parameters (e.g., a selection of the one or more configuration parameters already known to the first WCD 705 or the second WCD 710 or previously indicated by the network node or other network device), or explicit configuration information for the first WCD 705 or the second WCD 710 to use to configure the first WCD 705 or the second WCD 710, among other examples.

In some examples, the configuration information may not be expressly signaled to the first WCD 705 or the second WCD 710. For example, in some aspects, the configuration information may at least partially be defined by a wireless communication standard, such as the 3GPP. In such examples, the first WCD 705 (or another WCD) may not explicitly indicate such configuration information to the second WCD 710. For example, the first WCD 705 or the second WCD 710 may optionally obtain at least a portion of the configuration information from a configuration stored by the first WCD 705 or the second WCD 710 (e.g., an original equipment manufacturer (OEM) configuration). In some aspects, the configuration information may include a parameter or index that is indicative of information defined, or otherwise fixed, by a wireless communication standard, such as the 3GPP (e.g., rather than explicitly indicating the information).

In some aspects, the configuration information may indicate that the first WCD 705 or the second WCD 710 are to perform a channel coding operation. For example, the configuration information may indicate that the first WCD 705 is to encode communications using an LDPC code. The configuration information may indicate that the second WCD 710 is to decode communications using the LDPC code.

In some aspects, the configuration information may indicate one or more base graphs (or base graph matrices) to be used to generate the LDPC code. The one or more base graphs may be similar to the LDPC base graph 320, the PCM depicted in FIG. 4, or the base graph 505, among other examples. In some aspects, the one or more base graphs may include a base graph that includes a single punctured node. In some aspects, the single punctured node may include one or more parallel edges (e.g., an entry in the column, of the base graph matrix, corresponding to the single punctured node may include one or more entries with a value greater than one).

In some aspects, the configuration information may indicate that any base graph to be used for the LDPC code is to satisfy one or more conditions. The one or more conditions may include a check degree condition for base graphs that include a single punctured node. The check degree condition may indicate that at least one check node is connected to the single punctured node via a single edge. For example, the check degree condition may indicate that there are to be one or more check nodes that are connected to the single punctured node via one or more respective single edges (e.g., as indicated by a value of one (1) in an entry of a base graph matrix, where the entry is in a row corresponding to the single punctured node and in a column corresponding to a check node). In some aspects, by the base graph satisfying the check degree condition, a convergence time for the decoding operation may be reduced. For example, ensuring that at least one check node is connected to a punctured node via a single edge may enable a wireless communication device to start fast decoding because an initial decoding operation may be simplified. In LDPC codes, decoding may involve iterative message passing between variable nodes and check nodes. When a punctured node is connected to a check node with a single edge, the check node has fewer dependencies on other variable nodes, enabling the wireless communication device to resolve a value of the check node quickly and reliably. This initial resolution provides a foundation for subsequent decoding iterations, as the resolved check node can immediately contribute reliable information to neighboring nodes. As a result, the decoding operation at the wireless communication device may begin with a straightforward and rapid update, thereby reducing the overall number of iterations needed to achieve successful decoding, thereby enhancing the efficiency and speed of the decoding operation.

Additionally, or alternatively, the configuration information may indicate that the base graph is to satisfy a stability metric condition. The stability metric condition may indicate that a stability metric of a core portion of the base graph is to satisfy a threshold, such as a stability threshold. In some aspects, by the first WCD 705 and the second WCD 710 communicating one or more encoded communications that use an LDPC code that is based on a base graph that satisfies the stability metric condition, an error floor of the LDPC code may be improved, while also maintaining higher performance for the LDPC code. For example, the first WCD 705 and the second WCD 710 ensuring that the base graph satisfies the stability metric condition may reduce the likelihood of persistent errors that occur in some scenarios (such as at higher SNRs), thereby lowering the error floor. This may enable the base graph to have an optimized balance between the quantity of variable nodes having a degree of two (for improved SNR thresholds for some BLER targets) and a placement of the variable nodes having a degree of two within the base graph (for an improved error floor).

Additionally, or alternatively, the configuration information may indicate that the base graph is to satisfy a degree-2 condition. The degree-2 condition may indicate that a quantity of variable nodes having a degree of two (sometimes referred to as “degree two” nodes) in the core portion of the base graph is to satisfy a threshold. In some aspects, the degree-2 condition may indicate that a quantity of degree two variable nodes in the core portion is to be less than or equal to a threshold, such as a degree-2 threshold. In some aspects, the degree-2 condition may indicate that at least one of the degree two variable nodes in the core portion is to be mapped to a bit or position in a mapping scheme (such as the SBPM mapping scheme described in connection with FIG. 6) having relatively higher reliability levels. For example, degree two variable nodes may impact the threshold performance of LDPC codes. By strategically limiting their number, the first WCD 705 and the second WCD 710 may ensure that the LDPC code maintains a robust threshold, which enables a desired BLER at a given SNR to be achieved. Additionally, the base graph satisfying the degree-2 condition may improve the error floor for the LDPC code by reducing the likelihood of small cycles (such as short loops or closed paths within the Tanner graph representation of the LDPC code) for a decoding operation. Such small cycles (caused by a higher quantity of degree two variable nodes) may otherwise contribute to a higher error floor or degraded performance.

The first WCD 705 or the second WCD 710 may be configured based at least in part on the configuration information. In some aspects, the first WCD 705 or the second WCD 710 may be configured to perform one or more operations described herein based at least in part on the configuration information.

As shown by reference number 725, the first WCD 705 may encode a communication. The first WCD 705 may encode the communication using an LDPC code. The LDPC code may be based on, or generated using, a base graph that satisfies the one or more conditions, such as the check degree condition, the stability metric condition, or the degree-2 condition, among other examples.

The communication may include one or more information bits. For example, the first WCD 705 may obtain the one or more information bits, such as from an application layer or a transport layer in a protocol stack associated with the first WCD 705.

To generate the LDPC code, the first WCD 705 may use the base graph, which is a small graph capturing the macroscopic properties of the code. The base graph may be represented as a matrix with entries that denote the quantity of edges between the corresponding variable nodes (columns in the matrix) and check nodes (rows in the matrix). The first WCD 705 may perform a lifting operation using the base graph, where each entry in the base graph matrix is replaced by a circulant identity matrix of dimension Z×Z, where Z is the lift value. The lifting operation may result in a larger, lifted graph that maintains the degree distribution of the base graph while expanding the size of the base graph to accommodate a desired block length. In some examples, the base graph may include a single punctured node that is associated with one or more parallel edges or multiple edges. This reduces the convergence time for the decoding operation, such as the decoding operation described in connection with reference number 735.

After the lifted graph is generated, the first WCD 705 may use the lifted graph (or PCM) to encode the information bits of the communication. The encoding process may include the first WCD 705 mapping the information bits to the variable nodes in the lifted graph and performing a series of linear operations to generate a set of parity bits. The first WCD 705 may determine or compute the set of parity bits based on the connections (e.g., edges) defined by the lifted graph, ensuring that the resulting codeword satisfies the parity-check equations defined by the lifted graph. The encoding operation may result in an encoded communication. The encoded communication may include the information bits and the set of parity bits generated using the LDPC code. The systematic nature of the LDPC code means that the encoded communication consists of the original information bits followed by the set of parity bits. The encoding operation may improve reliability for the communication by providing an encoded communication with error-correcting capabilities enabled by the LDPC code.

As described above, the base graph that is used to generate the lifted graph (or PCM) for the LDPC code may satisfy the one or more conditions. In some examples, the first WCD 705 may determine whether the base graph satisfies the one or more conditions. If the base graph satisfies the one or more conditions, then the first WCD 705 may use the base graph to generate the LDPC code using for encoding the communication. If the base graph does not satisfy a condition of the one or more conditions, then the first WCD 705 may refrain from using the base graph to generate the LDPC code.

In some examples, the base graph may include a single punctured node to reduce convergence time associated with decoding the encoded communication. In some aspects, the single punctured node may be included in a parity portion of the base graph. For example, the single punctured node may be mapped to a column in the base graph matrix that is included in one or more core parity columns, such as the core parity columns 420. Including the single punctured node in the parity portion of the base graph may enable the integrity of information bits to be maintained, such as when the information bits are subject to probabilistic shaping, thereby maintaining performance gains. This approach simplifies decoding under good channel conditions, allowing direct verification of information bits using a cyclic redundancy check (CRC) without reconstructing punctured parity bits, thus reducing computational complexity. Additionally, puncturing parity nodes can lead to a more uniform reliability distribution across variable nodes, enhancing stability and maintaining a low error floor in high-throughput scenarios.

In some aspects, the check degree condition may indicate that at least one check node is to be connected to the single punctured node via a single edge. For example, the base graph matrix representing the base graph may include a single column mapped to the punctured node. The check degree condition may be met by the single column including at least one entry with the value of one indicating a single edge. For example, there should be at least one check node that punctured node is connected with via a single edge to start fast decoding as the second WCD 710 may be enabled to more quickly decode the check node connected to the single punctured node via a single edge, as compared to decoding a check node connected to the single punctured node via multiple edges.

In some aspects, the check degree condition may indicate that one or more first check nodes (C_{single}) that are connected to the single punctured node via a respective single edge are to have a lower degree than one or more second check nodes (Cₘᵤₗₜᵢₚₗₑ) that are connected to the single punctured node via multiple edges. For example, the degree of the check node(s) that are connected to the punctured node with single edge should be smaller than the other check nodes that are connected to the punctured node with multiple (double) edges. Having the check node(s) connected to the punctured node via a single edge possess a smaller degree than those check node(s) connected via multiple edges facilitates faster initial decoding by reducing the number of unknowns in the decoding operation, thereby accelerating convergence. This arrangement allows the second WCD 710 to efficiently resolve simpler check nodes first (e.g., the C_{single} check nodes), which can then propagate known values to more complex nodes (e.g., the Cₘᵤₗₜᵢₚₗₑ check nodes), optimizing the overall decoding operation.

In some aspects, rows of the base graph (e.g., of the base graph matrix) may be in an order of increasing degrees. For example, each row may correspond to a respective check node in the base graph. A check node may have a degree which indicates a quantity of connections or edges between the check node and variable node(s) in the base graph. In some aspects, the rows of the base graph matrix may be ordered (or re-ordered) to place the rows in order of decreasing degrees of corresponding check nodes. In some aspects, rows corresponding to the one or more first check nodes (C_{single}) may be ordered first in the base graph in order of decreasing degrees of corresponding check nodes. After ordering the one or more first check nodes (C_{single}), rows corresponding to other check nodes (Cₘᵤₗₜᵢₚₗₑ) may be ordered in the base graph in order of decreasing degrees of corresponding check nodes. This enables a natural decoding operation at the second WCD 710 in which the second WCD 710 can decode the check nodes in the order in which the corresponding rows are ordered in the base graph matrix. This reduces the complexity of the decoding operation and conserves processing resources that would have otherwise been associated with the second WCD 710 determining an order in which check nodes are to be decoded.

In some aspects, the base graph may satisfy the stability metric condition. For example, the stability metric condition may be satisfied by a stability metric of the core portion of the base graph satisfying a stability threshold. In some aspects, the stability threshold may be 0.4 or another value. The first WCD 705 may determine the stability metric for the core portion of the base graph. If the stability metric satisfies the stability threshold, then the first WCD 705 may determine that the stability metric condition is satisfied. In some aspects, if the stability metric is less than the stability threshold, then the first WCD 705 may determine that the stability metric condition is satisfied.

The stability metric may be a quantitative measure used to assess the robustness of the iterative decoding process against noise and errors. The stability metric may be indicative of the propensity of a decoding operation to converge to a correct solution as the quantity of iterations increases, such as in the presence of noise. For example, a stability condition may be a measure of a speed of error probability convergence as the quantity of iterations increases. For LDPC coding and quadrature phase shift keying (QPSK) modulation schemes, a Taylor series expansion of probability of error at an iteration l may be used to measure the stability condition. For example, the stability condition may be quantified as

$${x}_{l} = {ϵλ}^{′} ( 0 ) {ρ}^{′} {x}_{l - 1} + O ( {x}_{l - 1}^{2} ) ,$$

where xₗ is a bit error probability at an iteration l, ϵ is a channel parameter (such as a metric that characterizes the quality or reliability of the communication channel), λ is a polynomial associated with a variable node degree distribution of the base graph, and ρ is a polynomial associated with a check node degree distribution of the base graph. The stability metric may be calculated as ϵλ′(0)ρ′.

For QC-LDPC codes and QAM modulation, the stability of LDPC codes may be evaluated using a multi-edge type (MET) LDPC framework. The stability of LDPC codes may be evaluated using the MET LDPC framework by analyzing how different types of edges in the base graph of the LDPC code contribute to the overall decoding performance. In this framework, edges in the base graph may categorized based on roles or characteristics, such as a connection to variable nodes with different degrees or an association with different levels of reliability in the modulation scheme. By considering these distinctions, the MET framework provides a more granular view of how each edge type affects the iterative decoding process, particularly under varying channel conditions. In the MET framework, stability may be assessed by examining the spectral radius of a matrix that represents the interactions between different edge types during decoding. This matrix, which may be denoted as L×P, may capture the influence of degree distributions and edge connections on the error propagation within the base graph. L may be a Jacobian of a polynomial representation of the degree distribution of variable nodes in the base graph and P may be a Jacobian of a polynomial representation of the degree distribution of check nodes in the base graph.

A smaller spectral radius indicates that the iterative decoding process is more stable, meaning that errors are less likely to persist across iterations. By analyzing the spectral radius and other related metrics, the MET framework allows for a detailed evaluation of how the structure and distribution of edge types impact the ability of the LDPC code to converge to a correct solution, thus providing insights into the error floor and threshold performance of the LDPC code. In such examples, the stability metric may be, or may be based on, the spectral radius.

In some aspects, a density of degree two nodes within the base graph may impact or drive the value of the stability metric. For example, there may be a trade-off between a threshold performance and an error floor behavior of the core portion of the base graph. In some examples, the trade-off may be directly related to the degree two nodes included in the core portion. For example, a larger quantity of deg-2 nodes may result in a better threshold for larger BLER targets (10% or 1% BLER), but may result in a poor error floor (bad performance at 1e-4 BLER). Therefore, the base graph may satisfy a degree-2 condition. The degree-2 condition may indicate that a quantity of degree two variable nodes included in the core portion of the base graph is to satisfy a degree-2 threshold. In some aspects, the degree-2 threshold may be five or another value. For example, the degree-2 condition may indicate that a quantity of degree two variable nodes included in the core portion of the base graph is to be less than or equal to the degree-2 threshold. If the quantity of degree two variable nodes included in the core portion satisfies the degree-2 threshold, then the degree-2 condition may be satisfied.

In some aspects, the degree-2 condition may indicate that at least one degree two node in the core portion is to be mapped to a relatively higher reliability level of a modulation scheme used to modulate the encoded communication. For example, as shown by reference number 730, the first WCD 705 may map, using a mapping scheme, nodes of the base graph to bit positions of one or more modulation constellation symbols. “Bit positions” of one or more modulation constellation symbols refers to the specific locations within a symbol where individual bits are mapped, indicating how binary data is represented in the modulation scheme. The mapping scheme may be an SBPM scheme, such as the SBPM scheme described in connection with FIG. 6. In some aspects, at least one of the degree two nodes may be mapped to a bit position that has a reliability level that satisfies a reliability threshold. “Reliability level” for a bit position refers to the likelihood that the bit is correctly received and decoded, which may be influenced by a significance in the modulation constellation. The reliability threshold may indicate an allowable bit position in an order of bit positions from MSB to LSB for a modulation constellation symbol. For example, MSBs of modulation constellation symbols may have higher reliability levels than LSBs of the modulation constellation symbols. Therefore, when mapping the nodes of the base graph (or lifted graph) to bit positions of modulation constellation symbols, the first WCD 705 may map at least one of the degree two nodes in the core portion to a MSB (or a bit position close to the MSB, such as 1 or 2 bit positions from the MSB) to improve the reliability of transmitted information associated with the degree two nodes.

As shown by reference number 735, the first WCD 705 may provide or transmit, and the second WCD 710 may obtain or receive, the encoded communication. In some aspects, the first WCD 705 may provide or transmit, and the second WCD 710 may obtain or receive, the encoded communication via a shared channel or data channel, such as the PDSCH or the PUSCH. The encoded communication may include information bits and parity bits.

As shown by reference number 740, the second WCD 710 may demodulate the encoded communication. For example, based on the mapping scheme, nodes of the base graph may be mapped to bit positions of one or more modulation constellation symbols in a similar manner as described in connection with reference number 730. For example, SBPM may leverage the inherent reliability differences among bit positions within a modulation constellation to enhance decoding performance. The SBPM scheme may ensure that systematic bits, which are the most critical for accurate data reconstruction, are mapped to the MSB positions of the constellation symbols. These MSB positions are typically more reliable due to their higher resilience to noise and distortion. As the second WCD 710 demodulates the incoming signal, the second WCD 710 may prioritize the decoding of these systematic bits, taking advantage of the enhanced reliability to improve the overall accuracy of the decoded communication. By focusing on the more reliable MSB positions first, SBPM helps to reduce the error rate and improve the robustness of the communication system, even in challenging channel conditions. As described above, one or more degree two nodes in the base graph may be mapped to the more reliable MSB positions in the modulation constellation symbol, thereby improving the reliability and decoding performance for the degree two nodes.

As shown by reference number 745, the second WCD 710 may decode the encoded communication to obtain the communication. For example, the second WCD 710 may decode the encoded communication to obtain one or more information bits. The second WCD 710 may decode the communication using an LDPC code. The LDPC code may be based on, or generated using, the base graph that satisfies the one or more conditions, such as the check degree condition, the stability metric condition, or the degree-2 condition.

The LDPC code may be constructed by lifting the base graph to create a larger PCM that maintains the degree distribution and structural properties of the base graph. The second WCD 710 may apply an iterative decoding algorithm, such as the belief propagation or sum-product algorithm, to decode the encoded communication. The iterative decoding algorithm may iteratively update the probabilities of the variable nodes (representing the information and parity bits) based on the parity-check equations defined by the PCM. The goal may be to converge to a solution where all parity-check equations are satisfied, indicating that the correct codeword has been found.

During each iteration, the second WCD 710 may exchange messages between the variable nodes and check nodes, updating the likelihoods of each bit being a 0 or 1. In this context, “messages” may refer to the probabilistic information passed between the nodes in the Tanner graph representation of the LDPC code. In each iteration, the second WCD 710 may use the variable nodes send messages to the connected check nodes, indicating the current likelihood that each bit is a 0 or 1 based on the received encoded communication and the information received from other check nodes in previous iterations. The second WCD 710 may use the check nodes to process these incoming messages to determine the likelihood that the parity-check equations are satisfied. Based on this information, the check nodes send updated messages back to the variable nodes, providing new likelihoods for each bit. The decoding process may continue until the algorithm converges to a valid codeword or a maximum number of iterations is reached.

In some aspects, the second WCD 710 may perform a layered or sequential decoding operation to decode the encoded communication. For example, the second WCD 710 may first decode one or more first check nodes (C_{single}) that are connected to the single punctured node via a respective single edge. After decoding the one or more first check nodes, the second WCD 710 may decode one or more second check nodes (Cₘᵤₗₜᵢₚₗₑ) that are connected to the single punctured node via multiple edges. This enables the second WCD 710 to efficiently resolve simpler check nodes first (e.g., the C_{single} check nodes), which enables the second WCD 710 to propagate known values to more complex nodes (e.g., the Cₘᵤₗₜᵢₚₗₑ check nodes) during the decoding operation, optimizing the overall decoding operation. For example, the layered (sequential) decoding may start from the one or more first check nodes that are connected to punctured node(s) with single edge. Within the one or more first check nodes, the second WCD 710 may start decoding with a check node having a lowest degree. After decoding the check node having the lowest degree (within the C_{single} check nodes), the second WCD 710 may continue to decode any remaining C_{single} check node(s) in order of increasing degrees. After passing through all of the C_{single} check nodes, the second WCD 710 may attempt to decode the Cₘᵤₗₜᵢₚₗₑ check nodes in a similar manner. For example, within the Cₘᵤₗₜᵢₚₗₑ check nodes, the second WCD 710 may start decoding with a check node having a lowest degree. After decoding the check node having the lowest degree (within the Cₘᵤₗₜᵢₚₗₑ check nodes), the second WCD 710 may continue to decode any remaining Cₘᵤₗₜᵢₚₗₑ check node(s) in order of increasing degrees. This enables the second WCD 710 to resolve simpler constraints first, which may enable the second WCD 710 to quickly propagate known values throughout the LDPC code. This minimizes the initial computational complexity and helps establish a foundation of known bits that can be used to facilitate the decoding of more complex nodes, thereby reducing the convergence time and processing overhead associated with the decoding operation.

In some aspects, the rows of the base graph matrix representing the base graph may be ordered (or re-ordered) in an order of increasing degrees for corresponding check nodes. This enables the second WCD 710 to determine the order in which check nodes are to be decoded based on the order of the corresponding rows of the base graph matrix (e.g., without having to calculate or determine the degrees of each check node). This reduces the complexity and processing overhead associated with the layered or sequential decoding operation.

In some aspects, the second WCD 710 may determine that the base graph satisfies the one or more conditions, such as the check degree condition, the stability metric condition, or the degree-2 condition. For example, in a similar manner as described in connection with the first WCD 705 and reference number 725, the second WCD 710 may determine that the base graph satisfies the one or more conditions.

In some aspects, by first WCD 705 and the second WCD 710 communicating one or more encoded communications that use an LDPC code that is based on the base graph that satisfies the one or more conditions, an encoding operation and a decoding operation may be optimized to balance performance, fast convergence, and stability, among other examples. This may improve the overall decoding and encoding efficiency, improve reliability, or improve the robustness for encoded communications communicated in a wireless communication system.

As indicated above, FIG. 7 is provided as an example. Other examples may differ from what is described with regard to FIG. 7.

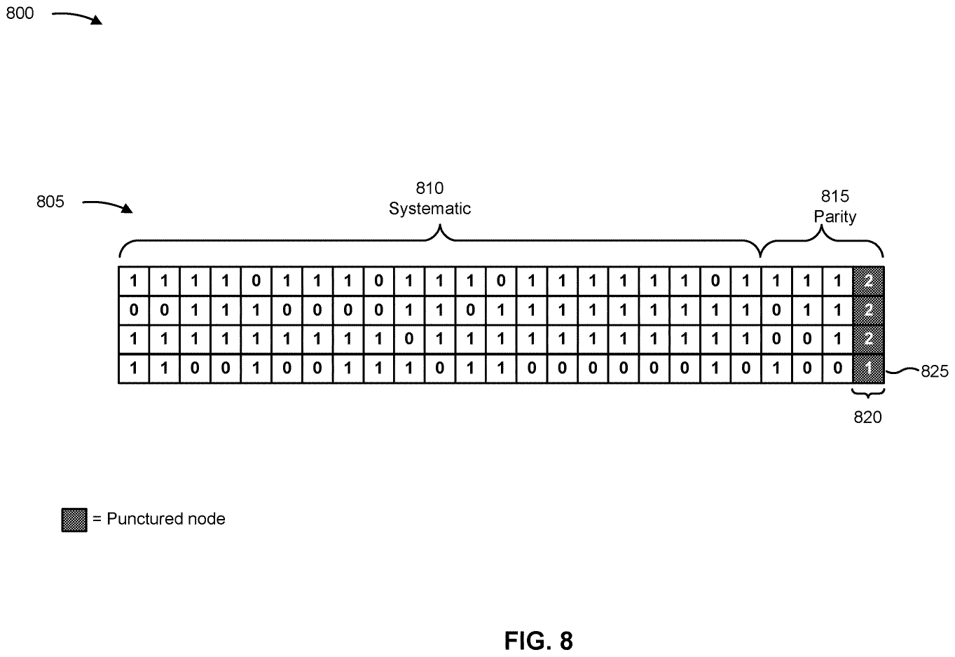

FIG. 8 is a diagram illustrating an example 800 of a base graph matrix 805 that satisfies a check degree condition for LDPC codes. The base graph matrix 805 may represent a base graph similar to the LDPC base graph 320.

As shown in FIG. 8, the base graph matrix 805 may include a systematic matrix 810 (or the systematic portion of the base graph matrix), and a parity matrix 815 (or the parity portion of the base graph matrix). The systematic matrix 810 may be a submatrix of the base graph matrix that corresponds to the portion of the base graph associated with the information bits. For example, the systematic matrix 810 may represent variable nodes to which the information bits are mapped. The parity matrix 815 may be associated with one or more parity bits. For example, the parity matrix 815 may represent variable nodes to which the parity bits are mapped.

The base graph represented by the base graph matrix 805 may satisfy a check degree condition, such as the check degree condition described in connection with FIG. 7. For example, the base graph may include a single punctured node represented by a column 820. In some aspects, as shown in FIG. 8, the single punctured node may be a parity node. For example, the column 820 may be included in the parity matrix 815 of the base graph matrix 805. The base graph may satisfy the check degree condition because the single punctured node (represented by the column 820) is connected to at least one check node via a single edge, as indicated by the value of one in the entry 825 of the column 820. For example, the value of one in the entry 825 of the column 820 may indicate that a check node represented by the row of the entry 825 is connected to the single punctured node by a single edge. A value of two in an entry indicates that a check node represented by the row of the entry with a value of two is connected to the single punctured node by two edges (e.g., parallel edges or double edges). For example, the check node represented by the column of the entry 825 may be included in the check node represented by the row of one or more first check nodes (C_{single}) that are connected to the single punctured node via a respective single edge. Other check nodes represented by rows with an entry with a value of two (or greater) may be included in the one or more second check nodes (Cₘᵤₗₜᵢₚₗₑ) that are connected to the single punctured node via multiple edges.

As indicated above, FIG. 8 is provided as an example. Other examples may differ from what is described with regard to FIG. 8.

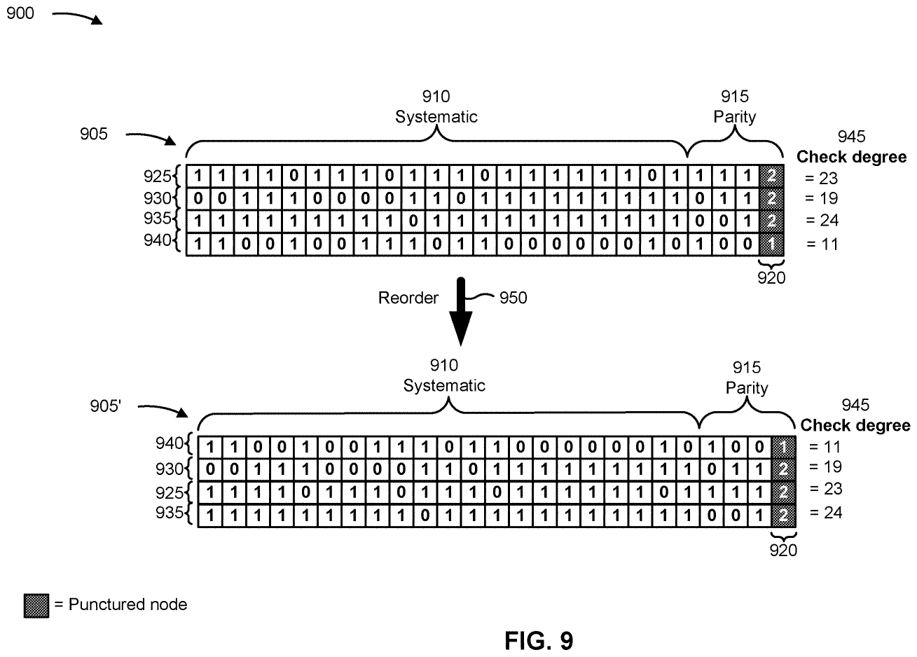

FIG. 9 is a diagram illustrating an example 900 of an optimized row order of a base graph matrix 905 for LDPC codes. The base graph matrix 905 may represent a base graph similar to the LDPC base graph 320.

As shown in FIG. 9, the base graph matrix 905 may include a systematic matrix 910 (or the systematic portion of the base graph matrix), and a parity matrix 915 (or the parity portion of the base graph matrix). The systematic matrix 910 may be a submatrix of the base graph matrix that corresponds to the portion of the base graph associated with the information bits. For example, the systematic matrix 910 may represent variable nodes to which the information bits are mapped. The parity matrix 915 may be associated with one or more parity bits. For example, the parity matrix 915 may represent variable nodes to which the parity bits are mapped. The base graph may include one or more punctured nodes, such as a single punctured node represented by a column 920. In some aspects, as shown in FIG. 9, the one or more punctured nodes may each be a parity node. For example, the column 920 may be included in the parity matrix 915 of the base graph matrix 905.

The base graph matrix 905 may include one or more rows, such as a row 925, a row 930, a row 935, and a row 940. Each row may represent a respective check node in the base graph. Each row may have a check degree 945. A check degree 945 for a given row may indicate a quantity of variable nodes that a check node, represented by the given row, is connected to. As another example, a check degree 945 for a given row may indicate a quantity of edges connected to a check node represented by the given row. For example, as shown in FIG. 9, the row 925 may have a check degree of 23, the row 930 may have a check degree of 19, the row 935 may have a check degree of 935, and the row 940 may have a check degree of 11.

As shown by reference number 950, the base graph matrix 905 may be re-ordered or re-arranged to generate a modified base graph matrix 905′. For example, the modified base graph matrix 905′ may have re-ordered rows compared to the base graph matrix 905. In some aspects, the re-ordering may include placing one or more rows representing one or more first check nodes (C_{single}) that are connected to the single punctured node via a respective single edge. For example, the row 940 may represent a check node included in the one or more first check nodes (C_{single}), as indicated by the value of one in the entry of the column 920 and the row 940. As shown in FIG. 9, the row 940 may be moved to a start of the modified base graph matrix 905′. For example, at the start of the modified base graph matrix 905′, the one or more first check nodes (C_{single}) may be ordered in an order of increasing degrees. For example, the one or more first check nodes (C_{single}) may be ordered from lowest degree to highest degree. For example, if there were a check node in the one or more first check nodes (C_{single}) with a degree of 10, then the row corresponding to the check node would be placed before the row 940 in the modified base graph matrix 905′. If there were a check node in the one or more first check nodes (C_{single}) with a degree of 12, then the row corresponding to the check node would be placed after the row 940 in the modified base graph matrix 905′.

After ordering rows representing the one or more first check nodes (C_{single}) in the modified base graph matrix 905′, the rows representing the one or more second check nodes (Cₘᵤₗₜᵢₚₗₑ) that are connected to the single punctured node via multiple edges may be ordered in the modified base graph matrix 905′. The rows representing the one or more second check nodes (Cₘᵤₗₜᵢₚₗₑ) may be ordered in an order of increasing degree. For example, the rows representing the one or more second check nodes (Cₘᵤₗₜᵢₚₗₑ) may be ordered (after the rows representing the one or more first check nodes (C_{single})) from a lowest degree to a highest degree. For example, as shown in FIG. 9, the modified base graph matrix 905′ may include the row 930, followed by the row 925, followed by the row 935 based on the increasing order of check degree 945.

As indicated above, FIG. 9 is provided as an example. Other examples may differ from what is described with regard to FIG. 9.

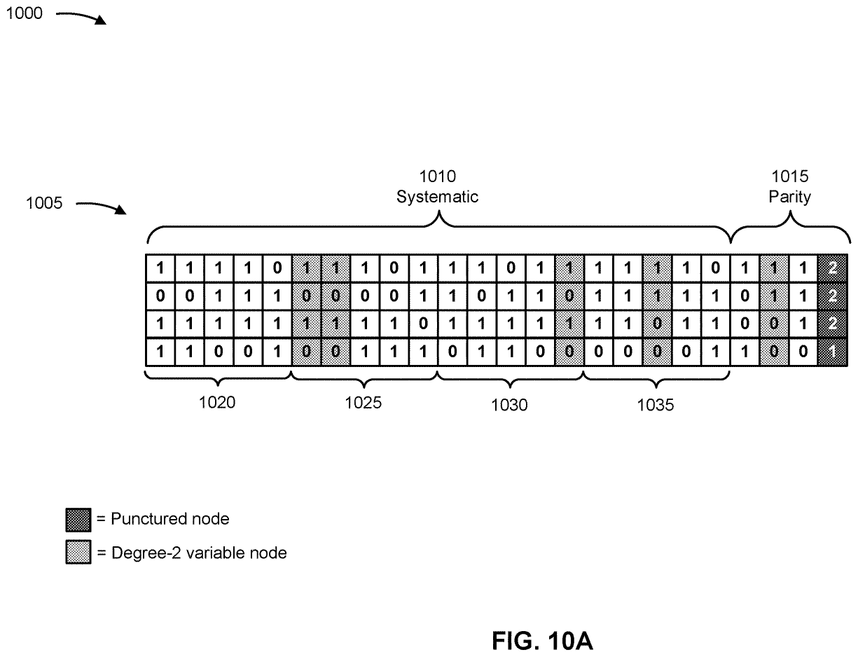

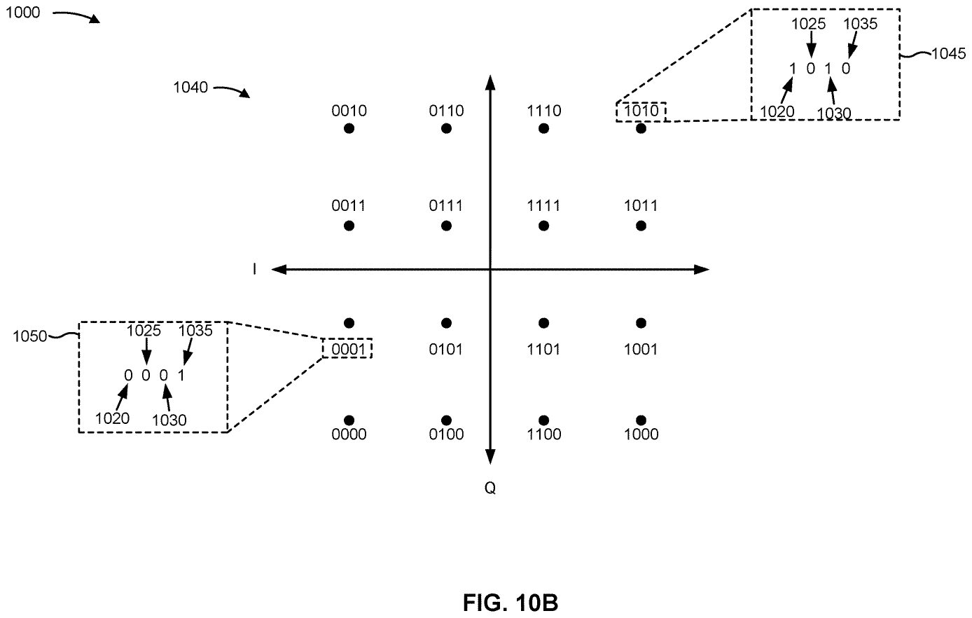

FIGS. 10A and 10B are diagrams illustrating an example 1000 of a base graph matrix 1005 that satisfies a degree-2 condition for LDPC codes. The base graph matrix 1005 may represent a base graph similar to the LDPC base graph 320 or the PCM 400. The base graph matrix 1005 may represent a core portion of the base graph.

As shown in FIG. 10A, the base graph matrix 1005 may include a systematic matrix 1010 (or the systematic portion of the base graph matrix), and a parity matrix 1015 (or the parity portion of the base graph matrix). The systematic matrix 1010 may be a submatrix of the base graph matrix that corresponds to the portion of the base graph associated with the information bits. For example, the systematic matrix 1010 may represent variable nodes to which the information bits are mapped. The parity matrix 1015 may be associated with one or more parity bits. For example, the parity matrix 1015 may represent variable nodes to which the parity bits are mapped. The base graph may include one or more punctured nodes, such as a single punctured node. In some aspects, as shown in FIG. 10, the one or more punctured nodes may be a parity node.

As shown in FIG. 10, variable nodes of the base graph (e.g., represented by columns of the base graph matrix 1005) may be mapped to bit position for a modulation constellation symbol (the modulation constellation and bit positions are shown in FIG. 10B), such as described in connection with reference number 730. For example, the bit positions may include a bit 1020, a bit 1025, a bit 1030, and a bit 1035 as an example. The bit 1020 may be an MSB of the modulation constellation symbol and the bit 1035 may be an LSB of the modulation constellation symbol. Using a mapping scheme, such as the SBPM scheme, the variable nodes included in the systematic matrix 1010 may be mapped to MSBs of the modulation constellation symbol. Because the MSB(s) may have relatively higher reliability levels, this may improve the performance or reliability for the information bits included in an encoded communication.

For example, an example modulation symbol constellation diagram 1040 is shown in FIG. 10B. A constellation diagram is a representation of a signal modulated by a digital modulation scheme, such as QAM (such as 16QAM, 64QAM, or 256QAM). A constellation diagram illustrates a signal as a two-dimensional scatter diagram with an x axis (e.g., a horizontal real axis representing an in-phase carrier, shown as an I component) and a y axis (e.g., a vertical imaginary axis representing a quadrature carrier, shown as a Q component). The angle of a constellation point, measured counterclockwise from the horizontal axis, represents a phase shift of a carrier wave from a reference phase. The distance to a constellation point, measured from the origin, represents the amplitude or power of the signal.

In a digital modulation system, information is transmitted as a series of samples, where each sample occupies a respective time period. During each sample, the carrier wave has a constant amplitude and phase value that is restricted to one of a finite number of values. Thus, each sample encodes one of a finite number of symbols, which in turn represents one or more binary digits (bits) of information. Each symbol is encoded as a combination of amplitude and phase of the carrier, and each symbol is represented by a point on the constellation diagram, called a constellation point. The constellation diagram shows all of the possible constellation symbols that can be transmitted by the system as a collection of points. During demodulation, a demodulator identifies a constellation point with a highest likelihood of corresponding to a received signal (e.g., a received sample) and recovers binary digits based at least in part on the symbol associated with the identified constellation point. The modulation symbol constellation diagram 1040 is an example of a 16QAM constellation diagram, which uses m=4 bits per symbol. For a constellation diagram with m bits per symbol (where m is greater than 4 and a multiple of 2), a first bit may indicate a sign of the I-component, a second bit may indicate a sign of the Q-component,

$$( \frac{m}{2} - 1 )$$

third bits may indicate an amplitude of the I-component, and

$$( \frac{m}{2} - 1 )$$

fourth bits may indicate an amplitude of the Q-component. Each constellation symbol may include four bits with different bit position, such as the bit 1020, the bit 1025, the bit 1030, and the bit 1035. As an example, a constellation symbol 1045 may include a value of 1 for the bit 1020, and value of 0 for the bit 1025, a value of 1 for the bit 1030, and a value of 0 the bit 1035. As another example, a constellation symbol 1050 may include a value of 0 for the bit 1020, and value of 0 for the bit 1025, a value of 0 for the bit 1030, and a value of 1 the bit 1035.

As shown in FIG. 10A, the base graph may satisfy the degree-2 condition based on a quantity of degree two variable nodes in the core portion of the base graph satisfying a degree-2 threshold. As shown in FIG. 10A, a degree two variable node may be a variable node with two edges (e.g., connected to two check nodes), as represented by a column with two entries having a value of one. As an example, the degree-2 threshold may be five. The base graph may satisfy the degree-2 condition because the base graph includes five degree two variable nodes in the core portion, which is less than or equal to the degree-2 threshold of five. In some aspects, at least some of the degree two variable nodes may be mapped to bit positions in the modulation constellation symbol having relatively higher reliability. For example, as shown in FIG. 10, two of the degree two variable nodes may be mapped to the bit 1025, which is near the MSB and therefore has relatively higher reliability (e.g., as compared to the bit 1035 or other bits closer to the LSB).

As indicated above, FIGS. 10A and 10B are provided as examples. Other examples may differ from what is described with regard to FIGS. 10A and 10B.

FIG. 11 is a diagram illustrating an example process 1100 performed, for example, at a wireless communication device or an apparatus of a wireless communication device. Example process 1100 is an example where the apparatus or the wireless communication device (e.g., the second WCD 710 or the WCD 170) performs operations associated with conditions LDPC codes.

As shown in FIG. 11, in some aspects, process 1100 may include obtaining an encoded communication (block 1110). For example, the wireless communication device (e.g., using communication manager 150 or reception component 1502, depicted in FIG. 15) may obtain an encoded communication, as described above.

As further shown in FIG. 11, in some aspects, process 1100 may include decoding, using an LDPC code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge (block 1120). For example, the wireless communication device (e.g., using communication manager 150 or decoding component 1508, depicted in FIG. 15) may decode, using an LDPC code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge, as described above.

Process 1100 may include additional aspects, such as any single aspect or any combination of aspects described below or in connection with one or more other processes described elsewhere herein.

In a first aspect, one or more other check nodes, of the one or more check nodes, are connected to the single punctured node via multiple edges, and the check degree condition indicates that a degree of the at least one check node is less than one or more degrees of the one or more other check nodes.

In a second aspect, alone or in combination with the first aspect, decoding the encoded communication to obtain the communication includes decoding the at least one check node, and decoding the one or more other check nodes after decoding the at least one check node.

In a third aspect, alone or in combination with one or more of the first and second aspects, the at least one check node includes multiple check nodes, and decoding the at least one check node includes decoding the multiple check nodes in an order that is based at least in part on degrees of respective check nodes from the multiple check nodes.

In a fourth aspect, alone or in combination with one or more of the first through third aspects, the one or more other check nodes include multiple check nodes, and decoding the one or more other check nodes includes decoding the multiple check nodes in an order that is based at least in part on degrees of respective check nodes from the multiple check nodes.

In a fifth aspect, alone or in combination with one or more of the first through fourth aspects, rows of the base graph are in an order of increasing degrees.

In a sixth aspect, alone or in combination with one or more of the first through fifth aspects, the base graph is in accordance with a stability metric condition.

In a seventh aspect, alone or in combination with one or more of the first through sixth aspects, the base graph includes a core portion that includes a systematic portion and a core parity portion, and the stability metric condition indicates that a stability metric of the core portion satisfies a threshold.

In an eighth aspect, alone or in combination with one or more of the first through seventh aspects, a core portion of the base graph includes one or more nodes that have a degree of two, and the base graph is in accordance with a degree-2 condition that indicates that a quantity of the one or more nodes satisfies a threshold.

In a ninth aspect, alone or in combination with one or more of the first through eighth aspects, process 1100 includes mapping, using a mapping scheme, nodes of the base graph to bit positions of one or more modulation constellation symbols, and at least one of the one or more nodes is mapped to a bit position that has a reliability level that satisfies a reliability threshold.

Although FIG. 11 shows example blocks of process 1100, in some aspects, process 1100 may include additional blocks, fewer blocks, different blocks, or differently arranged blocks than those depicted in FIG. 11. Additionally, or alternatively, two or more of the blocks of process 1100 may be performed in parallel.

FIG. 12 is a diagram illustrating an example process 1200 performed, for example, at a wireless communication device or an apparatus of a wireless communication device. Example process 1200 is an example where the apparatus or the wireless communication device (e.g., the first WCD 705 or the WCD 175) performs operations associated with conditions for LDPC codes.

As shown in FIG. 12, in some aspects, process 1200 may include encoding, using an LDPC code, a communication to obtain an encoded communication, the LDPC code being associated with a base graph that includes a single punctured node and one or more check nodes, and the base graph being in accordance with a check degree condition that indicates that at least one check node, of the one or more check nodes, is connected to the single punctured node via a single edge (block 1210). For example, the wireless communication device (e.g., using communication manager 155 or encoding component 1808, depicted in FIG. 18) may encode, using an LDPC code, a communication to obtain an encoded communication, the LDPC code being associated with a base graph that includes a single punctured node and one or more check nodes, and the base graph being in accordance with a check degree condition that indicates that at least one check node, of the one or more check nodes, is connected to the single punctured node via a single edge, as described above.

As further shown in FIG. 12, in some aspects, process 1200 may include providing, to a second wireless communication device, the encoded communication (block 1220). For example, the wireless communication device (e.g., using communication manager 155 or transmission component 1804, depicted in FIG. 18) may provide, to a second wireless communication device, the encoded communication, as described above.

Process 1200 may include additional aspects, such as any single aspect or any combination of aspects described below or in connection with one or more other processes described elsewhere herein.

In a first aspect, one or more other check nodes, of the one or more check nodes, are connected to the single punctured node via multiple edges, and the check degree condition indicates that a degree of the at least one check node is less than one or more degrees of the one or more other check nodes.

In a second aspect, alone or in combination with the first aspect, rows of the base graph are in an order of increasing degrees.

In a third aspect, alone or in combination with one or more of the first and second aspects, the base graph is in accordance with a stability metric condition.

In a fourth aspect, alone or in combination with one or more of the first through third aspects, the base graph includes a core portion that includes a systematic portion and a core parity portion, and the stability metric condition indicates that a stability metric of the core portion satisfies a threshold.

In a fifth aspect, alone or in combination with one or more of the first through fourth aspects, a core portion of the base graph includes one or more nodes that have a degree of two, and the base graph is in accordance with a degree-2 condition that indicates that a quantity of the one or more nodes satisfies a threshold.

In a sixth aspect, alone or in combination with one or more of the first through fifth aspects, process 1200 includes mapping, using a systematic bit prioritized mapping scheme, nodes of the base graph to bit positions of one or more modulation constellation symbols, and at least one of the one or more nodes is mapped to a bit position that has a reliability level that satisfies a reliability threshold.

Although FIG. 12 shows example blocks of process 1200, in some aspects, process 1200 may include additional blocks, fewer blocks, different blocks, or differently arranged blocks than those depicted in FIG. 12. Additionally, or alternatively, two or more of the blocks of process 1200 may be performed in parallel.

FIG. 13 is a diagram illustrating an example process 1300 performed, for example, at a wireless communication device or an apparatus of a wireless communication device. Example process 1300 is an example where the apparatus or the wireless communication device (e.g., the second WCD 710 or the WCD 170) performs operations associated with conditions for low-density parity check codes.

As shown in FIG. 13, in some aspects, process 1300 may include obtaining an encoded communication (block 1310). For example, the wireless communication device (e.g., using communication manager 150 or reception component 1502, depicted in FIG. 15) may obtain an encoded communication, as described above.

As further shown in FIG. 13, in some aspects, process 1300 may include decoding, using an LDPC code, the encoded communication to obtain a communication, the LDPC code being associated with a base graph that is in accordance with a stability metric condition (block 1320). For example, the wireless communication device (e.g., using communication manager 150 or decoding component 1508, depicted in FIG. 15) may decode, using an LDPC code, the encoded communication to obtain a communication, the LDPC code being associated with a base graph that is in accordance with a stability metric condition, as described above.

Process 1300 may include additional aspects, such as any single aspect or any combination of aspects described below or in connection with one or more other processes described elsewhere herein.

In a first aspect, the base graph includes a core portion that includes a systematic portion and a core parity portion, and the stability metric condition indicates that a stability metric of the core portion satisfies a threshold.

In a second aspect, alone or in combination with the first aspect, a core portion of the base graph includes one or more nodes that have a degree of two, and the base graph is in accordance with degree-2 condition that indicates that a quantity of the one or more nodes satisfies a threshold.

In a third aspect, alone or in combination with one or more of the first and second aspects, process 1300 includes mapping, using a mapping scheme, nodes of the base graph to bit positions of one or more modulation constellation symbols, and at least one of the one or more nodes is mapped to a bit position that has a reliability level that satisfies a reliability threshold.

In a fourth aspect, alone or in combination with one or more of the first through third aspects, the base graph includes a single punctured node and one or more check nodes, and the base graph is in accordance with a check degree condition that indicates that at least one check node, of the one or more check nodes, is connected to the single punctured node via a single edge.

In a fifth aspect, alone or in combination with one or more of the first through fourth aspects, one or more other check nodes, of the one or more check nodes, are connected to the single punctured node via multiple edges, and the check degree condition indicates that a degree of the at least one check node is less than one or more degrees of the one or more other check nodes.

In a sixth aspect, alone or in combination with one or more of the first through fifth aspects, decoding the encoded communication to obtain the communication includes decoding the at least one check node, and decoding the one or more other check nodes after decoding the at least one check node.

In a seventh aspect, alone or in combination with one or more of the first through sixth aspects, the at least one check node includes multiple check nodes, and decoding the at least one check node includes decoding the multiple check nodes in an order that is based at least in part on degrees of respective check nodes from the multiple check nodes.

In an eighth aspect, alone or in combination with one or more of the first through seventh aspects, the one or more other check nodes include multiple check nodes, and decoding the one or more other check nodes includes decoding the multiple check nodes in an order that is based at least in part on degrees of respective check nodes from the multiple check nodes.

In a ninth aspect, alone or in combination with one or more of the first through eighth aspects, rows of the base graph are in an order of increasing degrees.

Although FIG. 13 shows example blocks of process 1300, in some aspects, process 1300 may include additional blocks, fewer blocks, different blocks, or differently arranged blocks than those depicted in FIG. 13. Additionally, or alternatively, two or more of the blocks of process 1300 may be performed in parallel.

FIG. 14 is a diagram illustrating an example process 1400 performed, for example, at a wireless communication device or an apparatus of a wireless communication device. Example process 1400 is an example where the apparatus or the wireless communication device (e.g., the first WCD 705 or the WCD 175) performs operations associated with conditions for LDPC codes.

As shown in FIG. 14, in some aspects, process 1400 may include encoding, using an LDPC code, a communication to obtain an encoded communication, the LDPC code being associated with a base graph that is in accordance with a stability metric condition (block 1410). For example, the wireless communication device (e.g., using communication manager 155 or encoding component 1808, depicted in FIG. 18) may encode, using an LDPC code, a communication to obtain an encoded communication, the LDPC code being associated with a base graph that is in accordance with a stability metric condition, as described above.

As further shown in FIG. 14, in some aspects, process 1400 may include providing the encoded communication (block 1420). For example, the wireless communication device (e.g., using communication manager 155 or transmission component 1804, depicted in FIG. 18) may provide (or transmit) the encoded communication, as described above.

Process 1400 may include additional aspects, such as any single aspect or any combination of aspects described below or in connection with one or more other processes described elsewhere herein.

In a first aspect, the base graph includes a core portion that includes a systematic portion and a core parity portion, and the stability metric condition indicates that a stability metric of the core portion satisfies a threshold.

In a second aspect, alone or in combination with the first aspect, a core portion of the base graph includes one or more nodes that have a degree of two, and the base graph is in accordance with a degree-2 condition that indicates that a quantity of the one or more nodes satisfies a threshold.

In a third aspect, alone or in combination with one or more of the first and second aspects, process 1400 includes mapping, using a mapping scheme, nodes of the base graph to bit positions of one or more modulation constellation symbols, and at least one of the one or more nodes is mapped to a bit position that has a reliability level that satisfies a reliability threshold.

In a fourth aspect, alone or in combination with one or more of the first through third aspects, the base graph includes a single punctured node and one or more check nodes, and the base graph is in accordance with a check degree condition that indicates that at least one check node, of the one or more check nodes, is connected to the single punctured node via a single edge.

In a fifth aspect, alone or in combination with one or more of the first through fourth aspects, one or more other check nodes, of the one or more check nodes, are connected to the single punctured node via multiple edges, and the check degree condition indicates that a degree of the at least one check node is less than one or more degrees of the one or more other check nodes.

In a sixth aspect, alone or in combination with one or more of the first through fifth aspects, rows of the base graph are in an order of increasing degrees.

Although FIG. 14 shows example blocks of process 1400, in some aspects, process 1400 may include additional blocks, fewer blocks, different blocks, or differently arranged blocks than those depicted in FIG. 14. Additionally, or alternatively, two or more of the blocks of process 1400 may be performed in parallel.

FIG. 15 is a diagram of an example apparatus 1500 for wireless communication. The apparatus 1500 may be a wireless communication device, or a wireless communication device may include the apparatus 1500. In some aspects, the apparatus 1500 includes a reception component 1502 and a transmission component 1504, which may be in communication with one another (for example, via one or more buses or one or more other components). As shown, the apparatus 1500 may communicate with another apparatus 1506 (such as a UE, a base station, or another wireless communication device) using the reception component 1502 and the transmission component 1504. As further shown, the apparatus 1500 may include the communication manager 150. The communication manager 150 may include a decoding component 1508, among other examples. The communication manager 150 may be included in, or implemented via, a processing system (for example, the processing system 180 described in connection with FIG. 1) of the wireless communication device.

In some aspects, the apparatus 1500 may be configured to perform one or more operations described herein in connection with FIGS. 7-10. Additionally, or alternatively, the apparatus 1500 may be configured to perform one or more processes described herein, such as process 1100 of FIG. 11, process 1300 of FIG. 13, or a combination thereof. In some aspects, the apparatus 1500 or one or more components shown in FIG. 15 may include one or more components of the wireless communication device described in connection with FIG. 1. Additionally, or alternatively, one or more components shown in FIG. 15 may be implemented within one or more components described in connection with FIG. 1. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 1502 may receive communications, such as reference signals, control information, data communications, or a combination thereof, from the apparatus 1506. The reception component 1502 may provide received communications to one or more other components of the apparatus 1500. In some aspects, the reception component 1502 may perform signal processing on the received communications, and may provide the processed signals to the one or more other components of the apparatus 1500. In some aspects, the reception component 1502 may include one or more components of the wireless communication device described above in connection with FIG. 1, such as a radio, one or more RF chains, one or more transceivers, or one or more modems, each of which may in turn be coupled with one or more antennas of the wireless communication device.

The transmission component 1504 may transmit communications, such as reference signals, control information, data communications, or a combination thereof, to the apparatus 1506. In some aspects, one or more other components of the apparatus 1500 may generate communications and may provide the generated communications to the transmission component 1504 for transmission to the apparatus 1506. In some aspects, the transmission component 1504 may perform signal processing on the generated communications (such as filtering, amplification, modulation, digital-to-analog conversion, multiplexing, interleaving, mapping, or encoding, among other examples), and may transmit the processed signals to the apparatus 1506. In some aspects, the transmission component 1504 may include one or more components of the wireless communication device described above in connection with FIG. 1, such as a radio, one or more RF chains, one or more transceivers, or one or more modems, each of which may in turn be coupled with one or more antennas of the wireless communication device described in connection with FIG. 1. In some aspects, the transmission component 1504 may be co-located with the reception component 1502.

The reception component 1502 may obtain an encoded communication. The decoding component 1508 may decode, using an LDPC code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge.

The reception component 1502 may obtain an encoded communication. The decoding component 1508 may decode, using an LDPC code, the encoded communication to obtain a communication, the LDPC code being associated with a base graph that is in accordance with a stability metric condition.

The number and arrangement of components shown in FIG. 15 are provided as an example. In practice, there may be additional components, fewer components, different components, or differently arranged components than those shown in FIG. 15. Furthermore, two or more components shown in FIG. 15 may be implemented within a single component, or a single component shown in FIG. 15 may be implemented as multiple, distributed components. Additionally, or alternatively, a set of (one or more) components shown in FIG. 15 may perform one or more functions described as being performed by another set of components shown in FIG. 15.

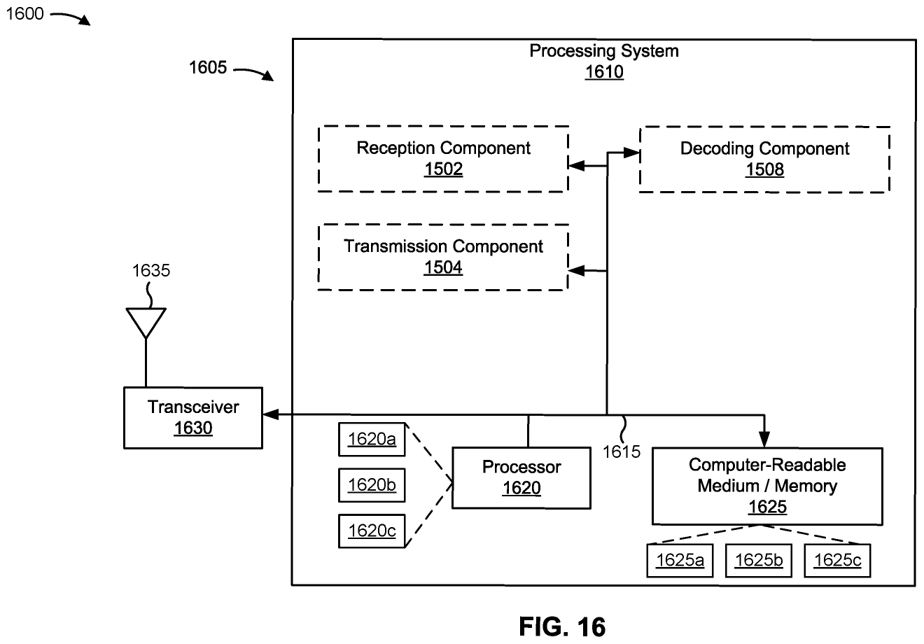

FIG. 16 is a diagram illustrating an example 1600 of a hardware implementation for an apparatus 1605 employing a processing system 1610. The apparatus 1605 may be a wireless communication device or may be at (e.g., included in) a wireless communication device. The processing system 1610 may be, or may be similar to, the processing system 140 of the UE 120, the processing system 145 of the network node 110, or the processing system 180 of the WCD 170 described in connection with FIG. 1.

The processing system 1610 may be implemented with a bus architecture, represented generally by the bus 1615. The bus 1615 may include any number of interconnecting buses and bridges depending on the specific application of the processing system 1610 and the overall design constraints. The bus 1615 links together various circuits including one or more processors or hardware components, represented by the processor (or processing circuitry) 1620, the illustrated components, and the computer-readable medium/memory (or memory circuitry) 1625. The processor 1620 may include multiple processors, such as processor 1620a, processor 1620b, and processor 1620c. The memory 1625 may include multiple memories, such as memory 1625a, memory 1625b, and memory 1625c The bus 1615 may also link various other circuits, such as timing sources, peripherals, voltage regulators, or power management circuits.

The processing system 1610 may be coupled to one or more transceivers 1630. A transceiver 1630 is coupled to one or more antennas 1635. The transceiver 1630 provides a means for communicating with various other apparatuses over a transmission medium. The transceiver 1630 receives a signal from the one or more antennas 1635, extracts information from the received signal, and provides the extracted information to the processing system 1610, specifically the reception component 1502. In addition, the transceiver 1630 receives information from the processing system 1610, specifically the transmission component 1504, and generates a signal to be applied to the one or more antennas 1635 based at least in part on the received information.

The processing system 1610 includes one or more processors 1620 coupled to a computer-readable medium/memory 1625. A processor 1620 is responsible for general processing, including the execution of software stored on the computer-readable medium/memory 1625. The software, when executed by the processor 1620, causes the processing system 1610 to perform the various functions described herein for any particular apparatus. The computer-readable medium/memory 1625 may also be used for storing data that is manipulated by the processor 1620 when executing software. The processing system further includes at least one of the illustrated components. The components may be software modules running in the processor 1620, resident/stored in the computer readable medium/memory 1625, one or more hardware modules coupled to the processor 1620, or some combination thereof.

In some aspects, the processing system 1610 may be a component of the WCD 170 or may be, may include, or may be included in the processing system 180 of the WCD 170 described in connection with FIG. 1. In some aspects, the apparatus 1605 for wireless communication includes means for obtaining an encoded communication; or means for decoding, using an LDPC code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge. Additionally, or alternatively, the apparatus 1605 for wireless communication includes means for obtaining an encoded communication; or decoding, using an LDPC code, the encoded communication to obtain a communication, the LDPC code being associated with a base graph that is in accordance with a stability metric condition. The aforementioned means may be one or more of the aforementioned components of the apparatus 1500 or the processing system 1610 of the apparatus 1605 configured to perform the functions recited by the aforementioned means. As described elsewhere herein, the processing system 1610 may include one or more components of the processing system 140, the processing system 145, or the processing system 180 described in connection with FIG. 1. In one configuration, the aforementioned means may be the processing system 180 or one or more components of the processing system 180 configured to perform the functions or operations recited herein.

FIG. 16 is provided as an example. Other examples may differ from what is described in connection with FIG. 16.

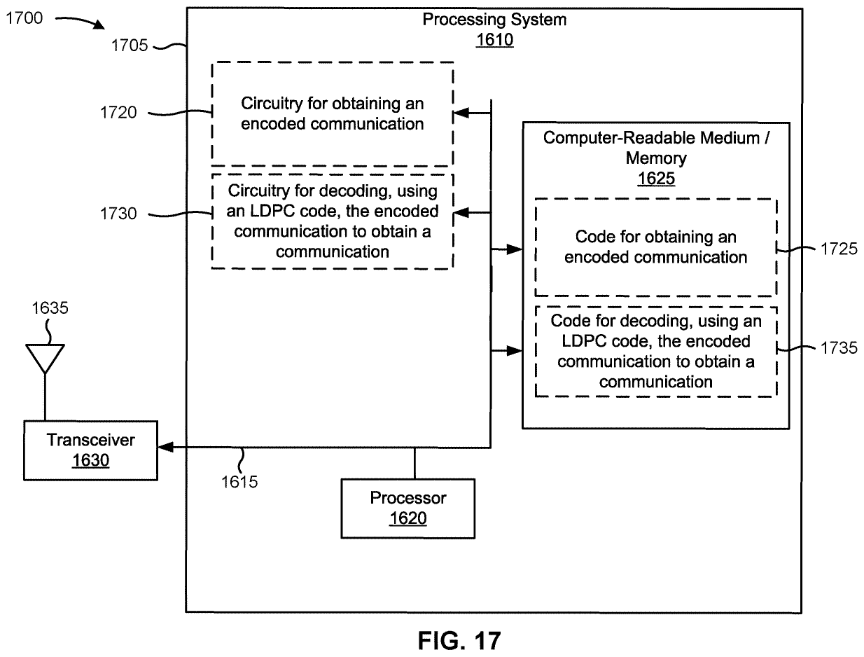

FIG. 17 is a diagram illustrating an example 1700 of an implementation of code and circuitry for an apparatus 1705. The apparatus 1705 may be a wireless communication device, or a wireless communication device may include the apparatus 1705.

As shown in FIG. 17, the apparatus 1705 may include circuitry for obtaining an encoded communication (circuitry 1720). For example, the circuitry 1720 may enable the apparatus 1705 to obtain an encoded communication.

As shown in FIG. 17, the apparatus 1705 may include, stored in computer-readable medium 1625, code for obtaining an encoded communication (code 1725). For example, the code 1725, when executed by processor 1620, may cause processor 1620 to cause transceiver 1630 to obtain an encoded communication.

As shown in FIG. 17, the apparatus 1705 may include circuitry for decoding, using an LDPC code, the encoded communication to obtain a communication (circuitry 1730). For example, the circuitry 1730 may enable the apparatus 1705 to decode, using an LDPC code, the encoded communication to obtain a communication. In some aspects, the LDPC code is associated with a base graph that includes a single punctured node and one or more check nodes, and the base graph is in accordance with a check degree condition that indicates that at least one check node, of the one or more check nodes, is connected to the single punctured node via a single edge. Additionally, or alternatively, the LDPC code is associated with a base graph that is in accordance with a stability metric condition.

As shown in FIG. 17, the apparatus 1705 may include, stored in computer-readable medium 1625, code for decoding, using the LDPC code, the encoded communication to obtain a communication (code 1735). For example, the code 1735, when executed by processor 1620, may cause processor 1620 to decode, using the LDPC code, the encoded communication to obtain a communication. In some aspects, the LDPC code is associated with a base graph that includes a single punctured node and one or more check nodes, and the base graph is in accordance with a check degree condition that indicates that at least one check node, of the one or more check nodes, is connected to the single punctured node via a single edge. Additionally, or alternatively, the LDPC code is associated with a base graph that is in accordance with a stability metric condition.

FIG. 17 is provided as an example. Other examples may differ from what is described in connection with FIG. 17.

FIG. 18 is a diagram of an example apparatus 1800 for wireless communication. The apparatus 1800 may be a wireless communication device, or a wireless communication device may include the apparatus 1800. In some aspects, the apparatus 1800 includes a reception component 1802 and a transmission component 1804, which may be in communication with one another (for example, via one or more buses or one or more other components). As shown, the apparatus 1800 may communicate with another apparatus 1806 (such as a UE, a base station, or another wireless communication device) using the reception component 1802 and the transmission component 1804. As further shown, the apparatus 1800 may include the communication manager 155. The communication manager 155 may include an encoding component 1808, among other examples. The communication manager 155 may be included in, or implemented via, a processing system (for example, the processing system 185 described in connection with FIG. 1) of the wireless communication device.

In some aspects, the apparatus 1800 may be configured to perform one or more operations described herein in connection with FIGS. 7-10. Additionally, or alternatively, the apparatus 1800 may be configured to perform one or more processes described herein, such as process 1200 of FIG. 12, process 1400 of FIG. 14, or a combination thereof. In some aspects, the apparatus 1800 or one or more components shown in FIG. 18 may include one or more components of the wireless communication device described in connection with FIG. 1. Additionally, or alternatively, one or more components shown in FIG. 18 may be implemented within one or more components described in connection with FIG. 1. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 1802 may receive communications, such as reference signals, control information, data communications, or a combination thereof, from the apparatus 1806. The reception component 1802 may provide received communications to one or more other components of the apparatus 1800. In some aspects, the reception component 1802 may perform signal processing on the received communications, and may provide the processed signals to the one or more other components of the apparatus 1800. In some aspects, the reception component 1802 may include one or more components of the wireless communication device described above in connection with FIG. 1, such as a radio, one or more RF chains, one or more transceivers, or one or more modems, each of which may in turn be coupled with one or more antennas of the wireless communication device.

The transmission component 1804 may transmit communications, such as reference signals, control information, data communications, or a combination thereof, to the apparatus 1806. In some aspects, one or more other components of the apparatus 1800 may generate communications and may provide the generated communications to the transmission component 1804 for transmission to the apparatus 1806. In some aspects, the transmission component 1804 may perform signal processing on the generated communications (such as filtering, amplification, modulation, digital-to-analog conversion, multiplexing, interleaving, mapping, or encoding, among other examples), and may transmit the processed signals to the apparatus 1806. In some aspects, the transmission component 1804 may include one or more components of the wireless communication device described above in connection with FIG. 1, such as a radio, one or more RF chains, one or more transceivers, or one or more modems, each of which may in turn be coupled with one or more antennas of the wireless communication device described in connection with FIG. 1. In some aspects, the transmission component 1804 may be co-located with the reception component 1802.

The encoding component 1808 may encode, using an LDPC code, a communication to obtain an encoded communication, the LDPC code being associated with a base graph that includes a single punctured node and one or more check nodes, and the base graph being in accordance with a check degree condition that indicates that at least one check node, of the one or more check nodes, is connected to the single punctured node via a single edge. The transmission component 1804 may provide, to a second wireless communication device, the encoded communication.

The encoding component 1808 may encode, using an LDPC code, a communication to obtain an encoded communication, the LDPC code being associated with a base graph that is in accordance with a stability metric condition. The transmission component 1804 may provide the encoded communication.

The number and arrangement of components shown in FIG. 18 are provided as an example. In practice, there may be additional components, fewer components, different components, or differently arranged components than those shown in FIG. 18. Furthermore, two or more components shown in FIG. 18 may be implemented within a single component, or a single component shown in FIG. 18 may be implemented as multiple, distributed components. Additionally, or alternatively, a set of (one or more) components shown in FIG. 18 may perform one or more functions described as being performed by another set of components shown in FIG. 18.

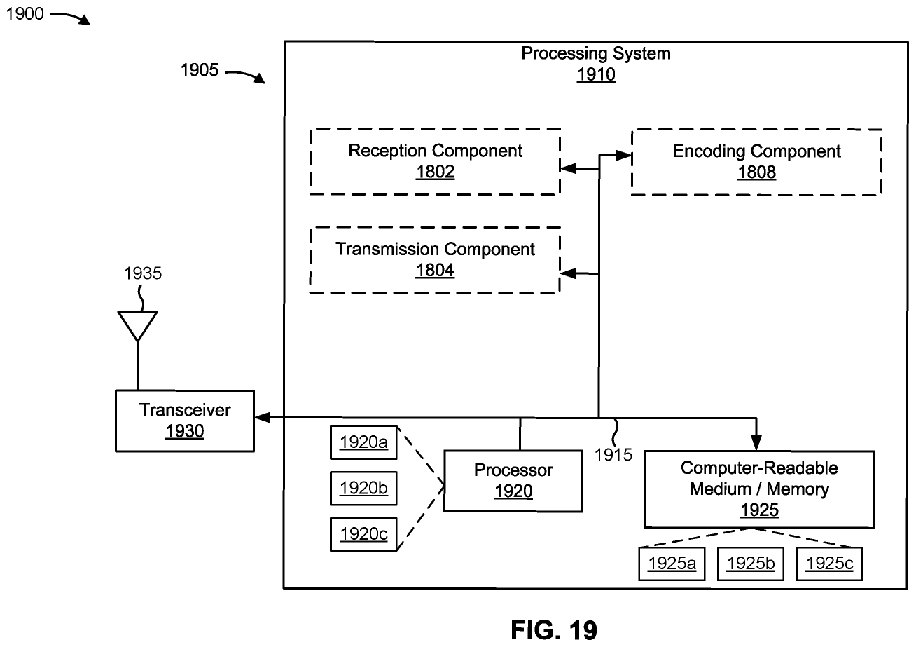

FIG. 19 is a diagram illustrating an example 1900 of a hardware implementation for an apparatus 1905 employing a processing system 1910. The apparatus 1905 may be a wireless communication device or may be at (e.g., included in) a wireless communication device. The processing system 1910 may be, or may be similar to, the processing system 140 of the UE 120, the processing system 145 of the network node 110, or the processing system 185 of the WCD 175 described in connection with FIG. 1.

The processing system 1910 may be implemented with a bus architecture, represented generally by the bus 1915. The bus 1915 may include any number of interconnecting buses and bridges depending on the specific application of the processing system 1910 and the overall design constraints. The bus 1915 links together various circuits including one or more processors or hardware components, represented by the processor (or processing circuitry) 1920, the illustrated components, and the computer-readable medium/memory (or memory circuitry) 1925. The processor 1920 may include multiple processors, such as processor 1920a, processor 1920b, and processor 1920c. The memory 1925 may include multiple memories, such as memory 1925a, memory 1925b, and memory 1925c The bus 1915 may also link various other circuits, such as timing sources, peripherals, voltage regulators, or power management circuits.

The processing system 1910 may be coupled to one or more transceivers 1930. A transceiver 1930 is coupled to one or more antennas 1935. The transceiver 1930 provides a means for communicating with various other apparatuses over a transmission medium. The transceiver 1930 receives a signal from the one or more antennas 1935, extracts information from the received signal, and provides the extracted information to the processing system 1910, specifically the reception component 1802. In addition, the transceiver 1930 receives information from the processing system 1910, specifically the transmission component 1804, and generates a signal to be applied to the one or more antennas 1935 based at least in part on the received information.

The processing system 1910 includes one or more processors 1920 coupled to a computer-readable medium/memory 1925. A processor 1920 is responsible for general processing, including the execution of software stored on the computer-readable medium/memory 1925. The software, when executed by the processor 1920, causes the processing system 1910 to perform the various functions described herein for any particular apparatus. The computer-readable medium/memory 1925 may also be used for storing data that is manipulated by the processor 1920 when executing software. The processing system further includes at least one of the illustrated components. The components may be software modules running in the processor 1920, resident/stored in the computer readable medium/memory 1925, one or more hardware modules coupled to the processor 1920, or some combination thereof.

In some aspects, the processing system 1910 may be a component of the UE 120 or may be, may include, or may be included in the processing system 140 of the UE 120 described in connection with FIG. 1. In some aspects, the apparatus 1905 for wireless communication includes means for encoding, using an LDPC code, a communication to obtain an encoded communication, the LDPC code being associated with a base graph that includes a single punctured node and one or more check nodes, and the base graph being in accordance with a check degree condition that indicates that at least one check node, of the one or more check nodes, is connected to the single punctured node via a single edge; or means for providing the encoded communication. Additionally, or alternatively, the apparatus 1905 for wireless communication includes means for encoding, using an LDPC code, a communication to obtain an encoded communication, the LDPC code being associated with a base graph that is in accordance with a stability metric condition; or means for providing the encoded communication. The aforementioned means may be one or more of the aforementioned components of the apparatus 1800 or the processing system 1910 of the apparatus 1905 configured to perform the functions recited by the aforementioned means. As described elsewhere herein, the processing system 1910 may include one or more components of the processing system 140, the processing system 145, or the processing system 185 described in connection with FIG. 1. In one configuration, the aforementioned means may be the processing system 185 or one or more components of the processing system 185 configured to perform the functions or operations recited herein.

FIG. 19 is provided as an example. Other examples may differ from what is described in connection with FIG. 19.

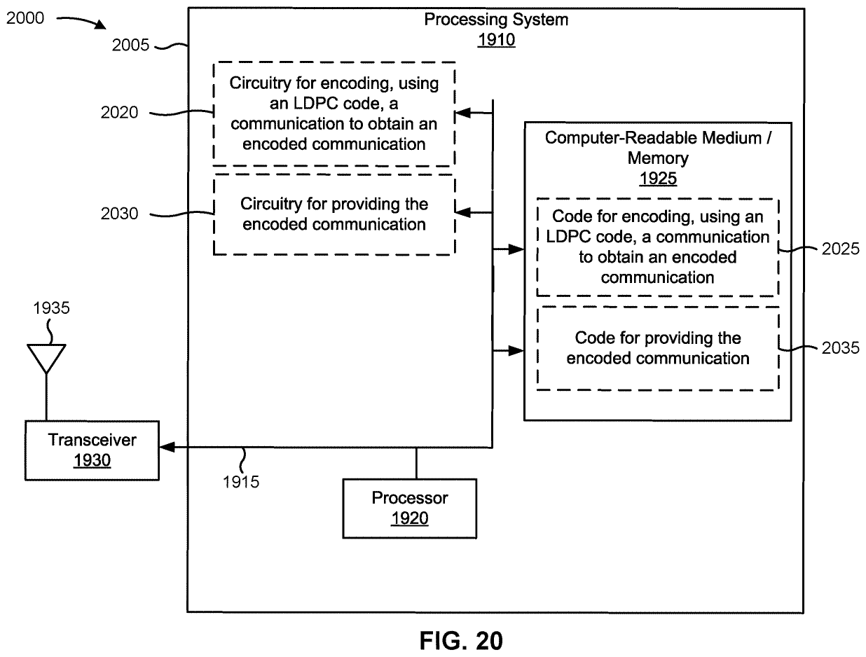

FIG. 20 is a diagram illustrating an example 2000 of an implementation of code and circuitry for an apparatus 2005. The apparatus 2005 may be a wireless communication device, or a wireless communication device may include the apparatus 2005.

As shown in FIG. 20, the apparatus 2005 may include circuitry for encoding, using an LDPC code, a communication to obtain an encoded communication (circuitry 2020). For example, the circuitry 2020 may enable the apparatus 2005 to encode, using an LDPC code, a communication to obtain an encoded communication. In some aspects, the LDPC code is associated with a base graph that includes a single punctured node and one or more check nodes, and the base graph is in accordance with a check degree condition that indicates that at least one check node, of the one or more check nodes, is connected to the single punctured node via a single edge. Additionally, or alternatively, the LDPC code is associated with a base graph that is in accordance with a stability metric condition.

As shown in FIG. 20, the apparatus 2005 may include, stored in computer-readable medium 1925, code for encoding, using an LDPC code, a communication to obtain an encoded communication (code 2025). For example, the code 2025, when executed by processor 1920, may cause processor 1920 to encode, using an LDPC code, a communication to obtain an encoded communication. In some aspects, the LDPC code is associated with a base graph that includes a single punctured node and one or more check nodes, and the base graph is in accordance with a check degree condition that indicates that at least one check node, of the one or more check nodes, is connected to the single punctured node via a single edge. Additionally, or alternatively, the LDPC code is associated with a base graph that is in accordance with a stability metric condition.

As shown in FIG. 20, the apparatus 2005 may include circuitry for providing the encoded communication (circuitry 2030). For example, the circuitry 2030 may enable the apparatus 2005 to provide the encoded communication.

As shown in FIG. 20, the apparatus 2005 may include, stored in computer-readable medium 1925, code for providing the encoded communication (code 2035). For example, the code 2035, when executed by processor 1920, may cause processor 1920 to cause transceiver 1930 to provide the encoded communication.

FIG. 20 is provided as an example. Other examples may differ from what is described in connection with FIG. 20.

The following provides an overview of some Aspects of the present disclosure:
Aspect 1: A method of wireless communication performed at a first wireless communication device, comprising: obtaining an encoded communication; and decoding, using a low-density parity check (LDPC) code, the encoded communication to obtain a communication, the LDPC code being associated with a base graph that includes a single punctured node and one or more check nodes, and the base graph being in accordance with a check degree condition that indicates that at least one check node, of the one or more check nodes, is connected to the single punctured node via a single edge.
Aspect 2: The method of Aspect 1, wherein one or more other check nodes, of the one or more check nodes, are connected to the single punctured node via multiple edges, and wherein the check degree condition indicates that a degree of the at least one check node is less than one or more degrees of the one or more other check nodes.
Aspect 3: The method of Aspect 2, wherein decoding the encoded communication to obtain the communication comprises: decoding the at least one check node; and decoding the one or more other check nodes after decoding the at least one check node.
Aspect 4: The method of Aspect 3, wherein the at least one check node includes multiple check nodes, and wherein decoding the at least one check node comprises: decoding the multiple check nodes in an order that is based at least in part on degrees of respective check nodes from the multiple check nodes.
Aspect 5: The method of any of Aspects 3-4, wherein the one or more other check nodes include multiple check nodes, and wherein decoding the one or more other check nodes comprises: decoding the multiple check nodes in an order that is based at least in part on degrees of respective check nodes from the multiple check nodes.
Aspect 6: The method of any of Aspects 1-5, wherein rows of the base graph are in an order of increasing degrees.
Aspect 7: The method of any of Aspects 1-6, wherein the base graph is in accordance with a stability metric condition.
Aspect 8: The method of Aspect 7, wherein the base graph includes a core portion that includes a systematic portion and a core parity portion, and wherein the stability metric condition indicates that a stability metric of the core portion satisfies a threshold.
Aspect 9: The method of any of Aspects 1-8, wherein a core portion of the base graph includes one or more nodes that have a degree of two, and wherein the base graph is in accordance with a degree-2 condition that indicates that a quantity of the one or more nodes satisfies a threshold.
Aspect 10: The method of Aspect 9, further comprising: mapping, using a mapping scheme, nodes of the base graph to bit positions of one or more modulation constellation symbols, and wherein at least one of the one or more nodes is mapped to a bit position that has a reliability level that satisfies a reliability threshold.
Aspect 11: A method of wireless communication performed at a first wireless communication device, comprising: encoding, using a low-density parity check (LDPC) code, a communication to obtain an encoded communication, the LDPC code being associated with a base graph that includes a single punctured node and one or more check nodes, and the base graph being in accordance with a check degree condition that indicates that at least one check node, of the one or more check nodes, is connected to the single punctured node via a single edge; and providing, to a second wireless communication device, the encoded communication.
Aspect 12: The method of Aspect 11, wherein one or more other check nodes, of the one or more check nodes, are connected to the single punctured node via multiple edges, and wherein the check degree condition indicates that a degree of the at least one check node is less than one or more degrees of the one or more other check nodes.
Aspect 13: The method of any of Aspects 11-12, wherein rows of the base graph are in an order of increasing degrees.
Aspect 14: The method of any of Aspects 11-13, wherein the base graph is in accordance with a stability metric condition.
Aspect 15: The method of Aspect 14, wherein the base graph includes a core portion that includes a systematic portion and a core parity portion, and wherein the stability metric condition indicates that a stability metric of the core portion satisfies a threshold.
Aspect 16: The method of any of Aspects 11-15, wherein a core portion of the base graph includes one or more nodes that have a degree of two, and wherein the base graph is in accordance with a degree-2 condition that indicates that a quantity of the one or more nodes satisfies a threshold.
Aspect 17: The method of Aspect 16, further comprising: mapping, using a systematic bit prioritized mapping scheme, nodes of the base graph to bit positions of one or more modulation constellation symbols, and wherein at least one of the one or more nodes is mapped to a bit position that has a reliability level that satisfies a reliability threshold.
Aspect 18: A method of wireless communication performed at a first wireless communication device, comprising: obtaining an encoded communication; and decoding, using a low-density parity check (LDPC) code, the encoded communication to obtain a communication, the LDPC code being associated with a base graph that is in accordance with a stability metric condition.
Aspect 19: The method of Aspect 18, wherein the base graph includes a core portion that includes a systematic portion and a core parity portion, and wherein the stability metric condition indicates that a stability metric of the core portion satisfies a threshold.
Aspect 20: The method of any of Aspects 18-19, wherein a core portion of the base graph includes one or more nodes that have a degree of two, and wherein the base graph is in accordance with degree-2 condition that indicates that a quantity of the one or more nodes satisfies a threshold.
Aspect 21: The method of Aspect 20, further comprising: mapping, using a mapping scheme, nodes of the base graph to bit positions of one or more modulation constellation symbols, and wherein at least one of the one or more nodes is mapped to a bit position that has a reliability level that satisfies a reliability threshold.
Aspect 22: The method of any of Aspects 18-21, wherein the base graph includes a single punctured node and one or more check nodes, and wherein the base graph is in accordance with a check degree condition that indicates that at least one check node, of the one or more check nodes, is connected to the single punctured node via a single edge.
Aspect 23: The method of Aspect 22, wherein one or more other check nodes, of the one or more check nodes, are connected to the single punctured node via multiple edges, and wherein the check degree condition indicates that a degree of the at least one check node is less than one or more degrees of the one or more other check nodes.
Aspect 24: The method of Aspect 23, wherein decoding the encoded communication to obtain the communication comprises: decoding the at least one check node; and decoding the one or more other check nodes after decoding the at least one check node.
Aspect 25: The method of Aspect 24, wherein the at least one check node includes multiple check nodes, and wherein decoding the at least one check node comprises: decoding the multiple check nodes in an order that is based at least in part on degrees of respective check nodes from the multiple check nodes.
Aspect 26: The method of any of Aspects 24-25, wherein the one or more other check nodes include multiple check nodes, and wherein decoding the one or more other check nodes comprises: decoding the multiple check nodes in an order that is based at least in part on degrees of respective check nodes from the multiple check nodes.
Aspect 27: The method of any of Aspects 22-26, wherein rows of the base graph are in an order of increasing degrees.
Aspect 28: A method of wireless communication performed at a first wireless communication device, comprising: encoding, using a low-density parity check (LDPC) code, a communication to obtain an encoded communication, the LDPC code being associated with a base graph that is in accordance with a stability metric condition; and providing the encoded communication.
Aspect 29: The method of Aspect 28, wherein the base graph includes a core portion that includes a systematic portion and a core parity portion, and wherein the stability metric condition indicates that a stability metric of the core portion satisfies a threshold.
Aspect 30: The method of any of Aspects 28-29, wherein a core portion of the base graph includes one or more nodes that have a degree of two, and wherein the base graph is in accordance with a degree-2 condition that indicates that a quantity of the one or more nodes satisfies a threshold.
Aspect 31: The method of Aspect 30, further comprising: mapping, using a mapping scheme, nodes of the base graph to bit positions of one or more modulation constellation symbols, and wherein at least one of the one or more nodes is mapped to a bit position that has a reliability level that satisfies a reliability threshold.
Aspect 32: The method of any of Aspects 28-31, wherein the base graph includes a single punctured node and one or more check nodes, and wherein the base graph is in accordance with a check degree condition that indicates that at least one check node, of the one or more check nodes, is connected to the single punctured node via a single edge.
Aspect 33: The method of Aspect 32, wherein one or more other check nodes, of the one or more check nodes, are connected to the single punctured node via multiple edges, and wherein the check degree condition indicates that a degree of the at least one check node is less than one or more degrees of the one or more other check nodes.
Aspect 34: The method of any of Aspects 28-33, wherein rows of the base graph are in an order of increasing degrees.
Aspect 35: An apparatus for wireless communication at a device, the apparatus comprising one or more processors; one or more memories coupled with the one or more processors; and instructions stored in the one or more memories and executable by the one or more processors to cause the apparatus to perform the method of one or more of Aspects 1-34.
Aspect 36: An apparatus for wireless communication at a device, the apparatus comprising one or more memories and one or more processors coupled to the one or more memories, the one or more processors configured to cause the device to perform the method of one or more of Aspects 1-34.
Aspect 37: An apparatus for wireless communication, the apparatus comprising at least one means for performing the method of one or more of Aspects 1-34.
Aspect 38: A non-transitory computer-readable medium storing code for wireless communication, the code comprising instructions executable by one or more processors to perform the method of one or more of Aspects 1-34.
Aspect 39: A non-transitory computer-readable medium storing a set of instructions for wireless communication, the set of instructions comprising one or more instructions that, when executed by one or more processors of a device, cause the device to perform the method of one or more of Aspects 1-34.
Aspect 40: A device for wireless communication, the device comprising a processing system that includes one or more processors and one or more memories coupled with the one or more processors, the processing system configured to cause the device to perform the method of one or more of Aspects 1-34.
Aspect 41: An apparatus for wireless communication at a device, the apparatus comprising one or more memories and one or more processors coupled to the one or more memories, the one or more processors individually or collectively configured to cause the device to perform the method of one or more of Aspects 1-34.
Aspect 42: A device comprising a processing system that includes one or more processors and one or more code-storing memories coupled with the one or more processors, the processing system configured to cause the device to perform the method of one or more of Aspects 1-34.
Aspect 43: A device comprising a processing system that includes processor circuitry and code-storing memory circuitry, the processing system configured to cause the device to perform the method of one or more of Aspects 1-34.
Aspect 44: An apparatus for wireless communication at a wireless communication device, comprising: a processing system that includes processor circuitry and memory circuitry that stores code and is coupled with the processor circuitry, the processing system configured to cause the wireless communication device to perform the method of one or more of Aspects 1-34.

It will be apparent that systems or methods described herein may be implemented in different forms of hardware or a combination of hardware and software. A component being configured to perform a function means that the component has a capability to perform the function, and does not require the function to be actually performed by the component, unless noted otherwise.

As used herein, the term “determine” or “determining” can encompass one or more of a wide variety of actions. For example, “determining” can include one or more of calculating, computing, processing, deriving, detecting, estimating, investigating, looking up, inferring, ascertaining, measuring, resolving, selecting, choosing, obtaining, identifying, interpreting, demodulating, decoding, reading, establishing, forming or generating, among other examples. In some such examples, determining can involve a processor performing some type of calculating, computing, deriving, estimating, inferring, ascertaining, resolving, predicting or other processing to obtain one or more numerical values, sets, elements or other information or results. In some other such examples, determining can involve a processor identifying, looking up, investigating or otherwise obtaining some type of value, set, element or other information or result from a table, a data structure, a database or other memory device or location. In some other such examples, determining can involve a processor identifying, interpreting, demodulating, decoding, detecting, reading or otherwise obtaining some type of value, set, element or other information or result signaled in, for example, a received wireless packet. In some other such examples, determining can involve a processor selecting or choosing one or more values, sets, elements or other information or results from a larger set of values, sets elements or other information or results. In some other such examples, determining can involve a processor performing a measurement, such as on a received signal.

As used herein, the articles “a” and “an” are intended to refer to one or more items and may be used interchangeably with “one or more” or “at least one.” As used herein, a phrase referring to “at least one of” or “one or more of” a list of items refers to any combination of those items, including single members. As an example, “at least one of: a, b, or c” is intended to cover: a, b, c, a-b, a-c, b-c, and a-b-c. Additionally, as used herein, a phrase referring to “a” or “an” element refers to one or more of such elements acting individually or collectively to perform the recited function(s). Additionally, as used herein, a “set” can refer to one or more items, and a “subset” can refer to a whole set or less than the whole set, but not an empty set. “Set,” “group,” and similar terms are intended to include one or more items and may be used interchangeably with “one or more.” Furthermore, as used herein, the term “or” is intended to be interpreted in the inclusive sense (such as when referring to a series) and may be used interchangeably with “and/or,” unless otherwise explicitly indicated (for example, if used in conjunction with “either” or “only one of”). For example, “A or B” may include A only, B only, or a combination of A and B. Also, as used herein, the terms “has,” “have,” “having,” “comprise,” “comprising,” “include” and “including,” and derivatives thereof or similar terms are intended to be open-ended terms that do not limit an element that they modify (for example, an element “having” A also may have B).

As used herein, the phrase “associated with” is intended to be interpreted in the inclusive sense, unless otherwise explicitly indicated. For example, the phrase “associated with” is not to be construed as a reference to a closed set of conditions, factors, criteria, elements, components, or actions, among other examples. Specifically, unless a phrase refers to “associated with only ‘a,’” or the equivalent in context, whatever it is that is “associated with ‘a,’” may be associated with “a” alone or associated with a combination of “a” and one or more other conditions, factors, criteria, elements, components, or actions, among other examples.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

Even though particular combinations of features are recited in the claims or disclosed in the specification, these combinations are not intended to limit the scope of all aspects described herein. Many of these features may be combined in ways not specifically recited in the claims or disclosed in the specification. The disclosure of various aspects includes each dependent claim in combination with every other claim in the claim set.

What is claimed is:

1. An apparatus at a first wireless communication device, comprising:
one or more memories; and
one or more processors coupled with the one or more memories and configured to cause the first wireless communication device to:
obtain an encoded communication; and
decode, using a low-density parity check (LDPC) code, the encoded communication to obtain a communication, wherein the LDPC code is associated with a base graph that includes a single punctured node and one or more check nodes, and wherein the base graph is in accordance with a check degree condition that indicates that at least one check node, of the one or more check nodes, is connected to the single punctured node via a single edge.

2. The apparatus of claim 1, wherein one or more other check nodes, of the one or more check nodes, are connected to the single punctured node via multiple edges, and wherein the check degree condition indicates that a degree of the at least one check node is less than one or more degrees of the one or more other check nodes.

3. The apparatus of claim 2, wherein to decode the encoded communication to obtain the communication, the one or more processors are configured to cause the first wireless communication device to:
decode the at least one check node; and
decode the one or more other check nodes after the decode of the at least one check node.

4. The apparatus of claim 3, wherein the at least one check node includes multiple check nodes, and wherein to decode the at least one check node, the one or more processors are configured to cause the first wireless communication device to:
decode the multiple check nodes in an order that is based at least in part on degrees of respective check nodes from the multiple check nodes.

5. The apparatus of claim 3, wherein the one or more other check nodes include multiple check nodes, and wherein to decode the one or more other check nodes, the one or more processors are configured to cause the first wireless communication device to:
decode the multiple check nodes in an order that is based at least in part on degrees of respective check nodes from the multiple check nodes.

6. The apparatus of claim 1, wherein rows of the base graph are in an order of increasing degrees.

7. The apparatus of claim 1, wherein the base graph is in accordance with a stability metric condition.

8. The apparatus of claim 7, wherein the base graph includes a core portion that includes a systematic portion and a core parity portion, and wherein the stability metric condition indicates that a stability metric of the core portion satisfies a threshold.

9. The apparatus of claim 1, wherein a core portion of the base graph includes one or more nodes that have a degree of two, and wherein the base graph is in accordance with a degree-2 condition that indicates that a quantity of the one or more nodes satisfies a threshold.

10. The apparatus of claim 9, wherein the one or more processors are configured to cause the first wireless communication device to:
map, using a mapping scheme, nodes of the base graph to bit positions of one or more modulation constellation symbols, and wherein at least one of the one or more nodes is mapped to a bit position that has a reliability level that satisfies a reliability threshold.

11. An apparatus at a first wireless communication device, comprising:
one or more memories; and
one or more processors coupled with the one or more memories and configured to cause the first wireless communication device to:
encode, using a low-density parity check (LDPC) code, a communication to obtain an encoded communication, wherein the LDPC code is associated with a base graph that includes a single punctured node and one or more check nodes, and wherein the base graph is in accordance with a check degree condition that indicates that at least one check node, of the one or more check nodes, is connected to the single punctured node via a single edge; and
provide, to a second wireless communication device, the encoded communication.

12. The apparatus of claim 11, wherein one or more other check nodes, of the one or more check nodes, are connected to the single punctured node via multiple edges, and wherein the check degree condition indicates that a degree of the at least one check node is less than one or more degrees of the one or more other check nodes.

13. The apparatus of claim 11, wherein rows of the base graph are in an order of increasing degrees.

14. The apparatus of claim 11, wherein the base graph is in accordance with a stability metric condition.

15. The apparatus of claim 14, wherein the base graph includes a core portion that includes a systematic portion and a core parity portion, and wherein the stability metric condition indicates that a stability metric of the core portion satisfies a threshold.

16. The apparatus of claim 11, wherein a core portion of the base graph includes one or more nodes that have a degree of two, and wherein the base graph is in accordance with a degree-2 condition that indicates that a quantity of the one or more nodes satisfies a threshold.

17. The apparatus of claim 16, wherein the one or more processors are configured to cause the first wireless communication device to:
map, using a mapping scheme, nodes of the base graph to bit positions of one or more modulation constellation symbols, and wherein at least one of the one or more nodes is mapped to a bit position that has a reliability level that satisfies a reliability threshold.

18. An apparatus at a first wireless communication device, comprising:
one or more memories; and
one or more processors coupled with the one or more memories and configured to cause the first wireless communication device to:
obtain an encoded communication; and
decode, using a low-density parity check (LDPC) code, the encoded communication to obtain a communication, wherein the LDPC code is associated with a base graph that is in accordance with a stability metric condition.

19. The apparatus of claim 18, wherein the base graph includes a core portion that includes a systematic portion and a core parity portion, and wherein the stability metric condition indicates that a stability metric of the core portion satisfies a threshold.

20. The apparatus of claim 18, wherein a core portion of the base graph includes one or more nodes that have a degree of two, and wherein the base graph is in accordance with a degree-2 condition indicates that a quantity of the one or more nodes satisfies a threshold.
